(19) United States
(12) Patent Application Publication
(10) Pub. No.: US 2025/0221130 A1
(43) Pub. Date: Jul. 3, 2025

(54) TRANSPARENT DISPLAY PANEL AND TRANSPARENT DISPLAY DEVICE

(71) Applicant: LG Display Co., Ltd., Seoul (KR)

(72) Inventors: SeonWoo Lee, Paju-si (KR); HwaDong Han, Paju-si (KR); Taekyun Kim, Paju-si (KR); Sanghyo Lee, Paju-si (KR)

(73) Assignee: LG Display Co., Ltd., Seoul (KR)

(21) Appl. No.: 18/968,420

(22) Filed: Dec. 4, 2024

(30) Foreign Application Priority Data
Dec. 27, 2023 (KR) 10-2023-0192306

(51) Int. Cl. H10H 29/49; H10H 29/85; H10H 29/855

(52) U.S. Cl. CPC H10H 29/49; H10H 29/8517; H10H 29/8552

(57) ABSTRACT

A transparent display device includes a first substrate including a transmissive area for transmitting external light and a non-transmissive area for not transmitting external light; a driving transistor in the non-transmissive area on the first substrate; an anode connection electrode on the driving transistor; and a light emitting element on the anode connection electrode, and including an anode electrode, a light emitting layer, and a cathode electrode. The anode electrode includes a first anode electrode and a second anode electrode. The anode connection electrode is electrically connected to the driving transistor at one side, and is extended toward the transmissive area from the non-transmissive area and electrically connected to each of the first anode electrode and the second anode electrode at the other side.

### CROSS-REFERENCE TO RELATED APPLICATION

This application claims the priority benefit of the Korean Patent Application No. 10-2023-0192306, filed on Dec. 27, 2023, the entire contents of which are hereby expressly incorporated for all purposes.

### BACKGROUND

### Field

The present disclosure relates to a display device, and more particularly, for example, without limitation, to a transparent display device that can reduce a size of a light emission area in which a dark spot occurs.

### Description of the Related Art

Recently, studies for a transparent display device in which a user can view objects or images positioned on a rear surface are actively ongoing. The transparent display device includes a display area on which an image is displayed, wherein the display area can include a transmissive area capable of transmitting external light. The transparent display device can have high light transmittance in the display area through the transmissive area.

Meanwhile, a plurality of subpixels provided with a circuit element and a light emitting element can be disposed in a non-transmissive area.

The description provided in the description of the related art section should not be assumed to be prior art merely because it is mentioned in or associated with the description of the related art section. The description of the related art section may include information that describes one or more aspects of the subject technology, and the description in this section does not limit the invention.

### SUMMARY

The inventors have recognized that, a defect can occur in the light emitting element of the plurality of subpixels due to moisture or oxygen permeated from the outside, whereby a dark spot can occur. As the transparent display device is provided with a transmissive area, a size of a light emission area is smaller than that of a general display device, whereby a defective subpixel in which a dark spot occurs can be easily seen to a user. Accordingly, the present disclosure has been made in view of the above problems, and it is an object of the present disclosure to provide a transparent display device that can reduce a size of a light emission area in which a dark spot occurs.

It is another object of the present disclosure to provide a transparent display device that can minimize or reduce a decrease in light transmittance due to an anode connection electrode for connecting divided anode electrodes.

It is yet another object of the present disclosure to provide a transparent display device that can implement environment/social/governance (ESG) by attenuating occurrence of greenhouse gas that can occur due to a manufacturing process for producing the transparent display device.

In addition to the objects of the present disclosure as mentioned above, additional objects and features of the present disclosure can be clearly understood by those skilled in the art from the following description of the present disclosure.

To achieve these and other advantages and in accordance with the purpose of the disclosure, as embodied and broadly described herein, a transparent display device includes a first substrate including a transmissive area for transmitting external light and a non-transmissive area for not transmitting external light; a driving transistor in the non-transmissive area on the first substrate; an anode connection electrode on the driving transistor; and a light emitting element on the anode connection electrode, and including an anode electrode, a light emitting layer, and a cathode electrode. The anode electrode includes a first anode electrode and a second anode electrode. The anode connection electrode is electrically connected to the driving transistor at one side, and is extended toward the transmissive area and electrically connected to each of the first anode electrode and the second anode electrode at the other side.

In accordance with another aspect of the present disclosure, a transparent display device includes a plurality of transmissive areas transmitting external light; a non-transmissive area between adjacent transmissive areas among the plurality of transmissive areas; a driving transistor in the non-transmissive area, and including an active layer, a gate electrode, a source electrode and a drain electrode; an anode connection electrode on the driving transistor; and a light emitting element on the anode connection electrode, and including an anode electrode, a light emitting layer, and a cathode electrode. The anode electrode includes a first anode electrode and a second anode electrode. The anode connection electrode electrically connects the first anode electrode and the second anode electrode to one of the source electrode and the drain electrode of the driving transistor.

It is to be understood that both the foregoing general description and the following detailed description of the present disclosure are by way of example and are intended to provide further explanation of the disclosure as claimed.

### BRIEF DESCRIPTION OF THE DRAWINGS

The accompanying drawings, which are included to provide a further understanding of the present disclosure and are incorporated in and constitute a part of this application, illustrate embodiments of the disclosure and together with the description serve to explain the principles of the disclosure. In the drawings:

FIG. 1 is a schematic plan view illustrating a transparent display device according to an example embodiment of the present disclosure;

FIG. 2 is a view illustrating an example of a pixel provided in an area A of FIG. 1;

FIG. 3 is a circuit view illustrating an example of a subpixel of FIG. 2;

FIG. 4 is a view illustrating an example of a plurality of subpixels and a plurality of signal lines, which are provided in an area B of FIG. 2;

FIG. 5 is a plan view illustrating an example of an area C of FIG. 4;

FIG. 6 is a plan view illustrating cutting areas of an anode connection electrode;

FIG. 7 is a cross-sectional view illustrating an example of I-I′ of FIG. 5;

FIG. 8 is a cross-sectional view illustrating an example of II-II′ of FIG. 5;

FIG. 9 is a view illustrating an example in which a cathode electrode and an encapsulation layer are damaged during laser cutting;

FIG. 10 is a plan view illustrating another example of an area C of FIG. 4;

FIG. 11 is a cross-sectional view illustrating an example of III-III′ of FIG. 10; and

FIG. 12 is a view illustrating an example in which a contact hole is formed in an area that overlaps an active layer.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure, and implementation methods thereof will be clarified through following example embodiments described with reference to the accompanying drawings. The present disclosure can, however, be embodied in different forms and should not be construed as limited to the example embodiments set forth herein. Rather, these example embodiments are provided so that this disclosure will be thorough and complete, and will fully convey the scope of the present disclosure to those skilled in the art. Furthermore, the protected scope of the present disclosure is defined by claims and their equivalents.

A shape, a size, a ratio, an angle, and a number disclosed in the drawings for describing example embodiments of the present disclosure are merely an example, and thus the present disclosure is not limited to the illustrated details. Like reference numerals refer to like elements throughout. In the following description, when the detailed description of the relevant known technology is determined to unnecessarily obscure the important point of the present disclosure, the detailed description will be omitted. In a case where “include,” “have,” “comprise,” “contain,” “constitute,” “make up of,” “formed of,” and “consist of” described in the present disclosure are used, another part can be added unless a more limiting term like “only” is used. The terms of a singular form can include plural forms, and vice versa, unless referred to the contrary.

The shapes, sizes, dimensions (e.g., length, width, height, thickness, radius, diameter, area, etc.), ratios, angles, numbers of elements, and the like illustrated in the accompanying drawings for describing the example embodiments of the present disclosure are merely examples, and the present disclosure is not limited thereto. Like reference numerals generally denote like elements throughout the specification.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In construing an element, the element is construed as including an error range although there is no explicit description.

In describing a positional relationship, for example, where a position relation between two parts is described as “on”, “above”, “over”, “below”, “under”, “beside”, “beneath”, “near”, “close to,” “adjacent to”, “on a side of”, “next”, one or more other parts can be disposed between the two parts unless a more limiting term like “just” or “direct” is used.

Spatially relative terms, such as “under,” “below,” “beneath”, “lower,” “over,” “upper” and the like, may be used herein for ease of description to describe one element or feature's relationship to another element(s) or feature(s) as illustrated in the figures. It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the example term “below” can encompass both an orientation of below and above. Similarly, the example term “above” or “over” can encompass both an orientation of “above” and “below”.

Where an element or layer is described as disposed “on” another element or layer, another layer or another element may be interposed directly on the other element or therebetween.

In describing a temporal relationship, for example, when a temporal precedence relationship is described such as “after”, “following”, “next”, “before”, etc., it can include cases that are not consecutive unless a more limiting term like “immediately” or “directly” are used.

It will be understood that, although the terms “first,” “second,” “A”, “B”, “(A)”, or “(B)”, etc., can be used herein to describe various elements, these elements should not be limited by these terms. These terms are only used to distinguish one element from another. For example, a first element could be termed a second element, and, similarly, a second element could be termed a first element, without departing from the scope of the present disclosure.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

A term “device” used herein may refer to a display device including a display panel and a driver for driving the display panel. Examples of the display device may include a light emitting element, and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

Features of various example embodiments of the present disclosure can be partially or totally coupled to or combined with each other, and can be variously inter-operated and driven technically. The example embodiments of the present disclosure can be carried out independently from each other or can be carried out together with a co-dependent relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

Hereinafter, with reference to the accompanying drawings, a display device according to example embodiments of the present disclosure is described. In assigning reference numerals to the components in each drawing, the same component can have the same numeral as far as possible, even if it is shown in different drawings. In addition, where a detailed description of the relevant known technology may unnecessarily obscure important or significant aspects of the present disclosure, such detailed description may be omitted.

Hereinafter, the example embodiment of the present disclosure will be described in detail with reference to the accompanying drawings.

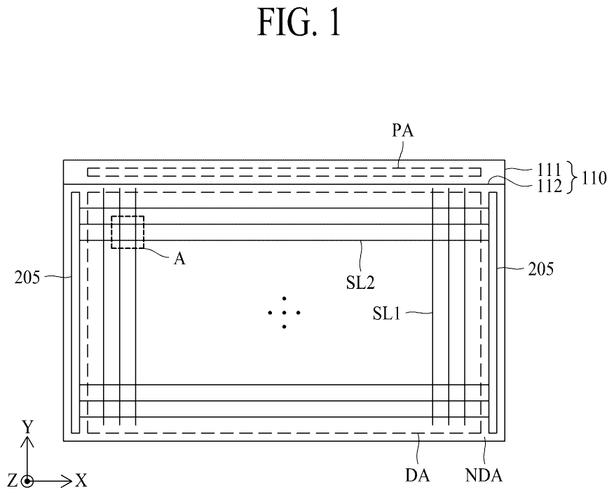

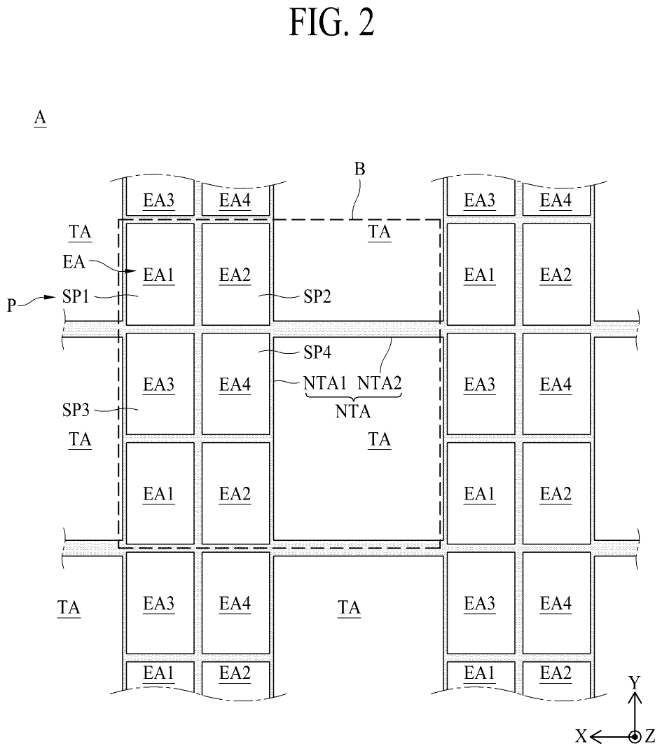

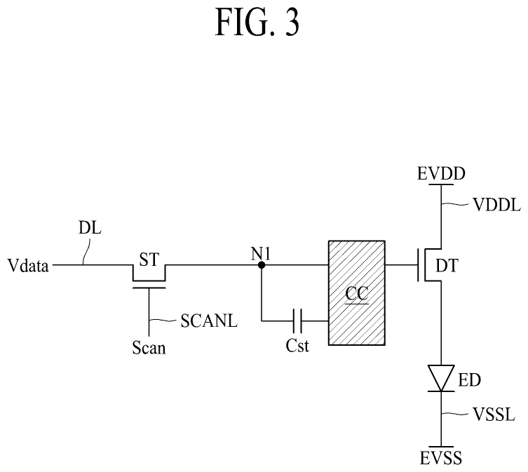

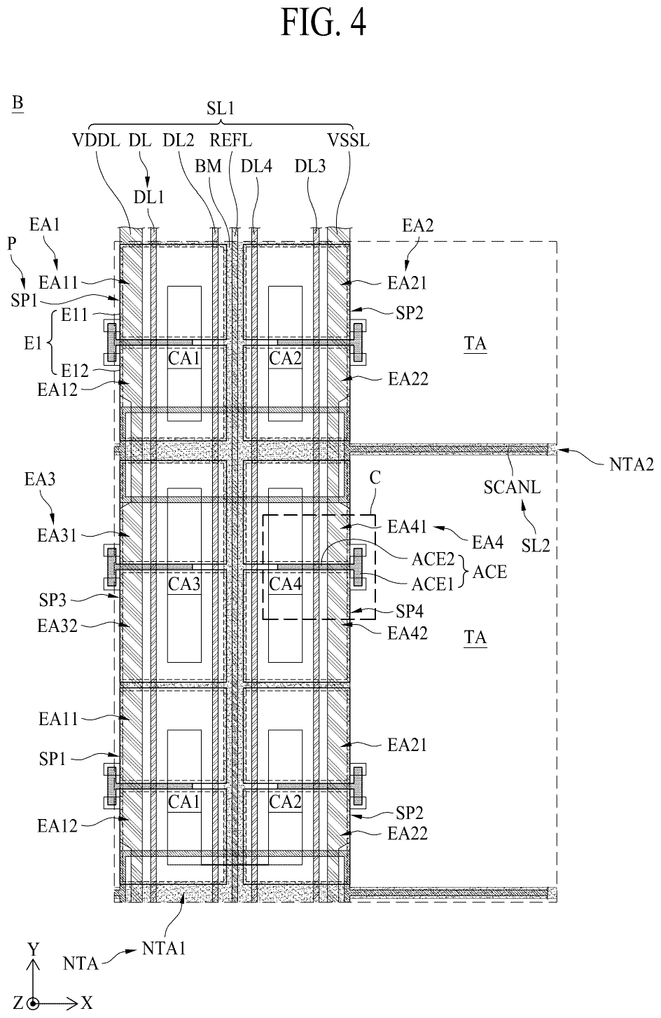

FIG. 1 is a schematic plan view illustrating a transparent display device according to one example embodiment of the present disclosure. FIG. 2 is a view illustrating an example of a pixel provided in an area A of FIG. 1. FIG. 3 is a circuit view illustrating an example of a subpixel of FIG. 2. FIG. 4 is a view illustrating an example of a plurality of subpixels and a plurality of signal lines, which are provided in an area B of FIG. 2.

Hereinafter, X-axis represents a direction parallel with a gate line, Y-axis represents a direction parallel with a data line, and Z-axis represents a height direction of a transparent display device 100. However, the present disclosure is not limited thereto, for example, Y-axis may represent a direction parallel with a gate line, X-axis may represent a direction parallel with a data line, and Z-axis may represent a height direction of a transparent display device 100.

Although the transparent display device 100 according to an example embodiment of the present disclosure will be described to be implemented as an organic light emitting display (OLED), it can be also implemented as a liquid crystal display (LCD), a plasma display panel (PDP), a quantum dot light emitting display (QLED), or an electrophoresis display, and the present disclosure is not limited thereto.

As shown in FIG. 1, the transparent display device 100 according to an example embodiment of the present disclosure includes a transparent display panel 110.

The transparent display panel 110 includes a first substrate 111 and a second substrate 112, which face each other. The second substrate 112 can be an encapsulation substrate. The first substrate 111 can be a plastic film, a glass substrate or a silicon wafer substrate formed using a semiconductor process. The second substrate 112 can be a plastic film, a glass substrate or an encapsulation film. The first substrate 111 and the second substrate 112 can be made of a transparent material.

The transparent display panel 110 can be categorized into a display area DA in which pixels P are formed to display an image, and a non-display area NDA for not displaying an image. The non-display area NDA may be an area adjacent to the display area DA. Further, the non-display area NDA may be an area disposed adjacent to the display area DA and configured to surround the display area DA. However, the present disclosure is not limited thereto.

For example, the non-display area NDA may include a first non-display area located outside the display area DA in a first direction, a second non-display area located outside the display area DA in a second direction intersecting the first direction, a third non-display area located outside the display area DA in the opposite direction to the first direction, and a fourth non-display area located outside the display area DA in the direction opposite to the second direction.

For another example, a boundary area between the display area DA and the non-display area NDA may be bent so that the non-display area NDA may be located below the display area. In this case, when the user looks at the display device from the front, there may be little or no non-display area NDA visible to the user.

The non-display area NDA can include a pad area PA in which pads are disposed, and at least scan driver 205. A plurality of pads can be disposed in the pad area PA. Since a size of the first substrate 111 is greater than that of the second substrate 112, a portion of the first substrate 111 can be exposed without being covered by the second substrate 112. Pads such as power pads and data pads can be provided in a portion of the first substrate 111, which is exposed without being covered by the second substrate 112.

The scan driver 205 can be formed in the non-display area NDA outside one side or both sides of the display area DA in a gate driver in panel (GIP) mode. Alternatively, the scan driver 205 can be manufactured as a driving chip, packaged on a flexible film and attached to the non-display area NDA outside one side or both sides of the display area DA in a tape automated bonding (TAB) mode.

First signal lines SL1, second signal lines SL2, and pixels P can be provided in the display area DA. The first signal lines SL1 can be extended in a first direction (e.g., Y-axis direction) in the display area DA. For example, the first signal lines SL1 can be data lines, but are not limited thereto. The first signal lines SL1 can include at least one of a first power line, a second power line, or a reference line.

The second signal lines SL2 can be extended in a second direction (e.g., X-axis direction) in the display area DA, and can cross the first signal lines SL1 in the display area DA. For example, the second signal lines SL2 can be scan lines, but are not limited thereto.

As shown in FIG. 2, the pixels P are provided in an area where the first signal line SL1 is provided or an area where the first signal line SL1 and the second signal line SL2 cross each other, and can emit predetermined light to display an image.

Each of the plurality of subpixels SP is a minimum unit which configures the display area and n subpixels SP form one pixel. Each of the plurality of subpixels SP may emit light having different wavelengths from each other. The plurality of subpixels may include first to third subpixels which emit different color light from each other. For example, the plurality of subpixels SP may include red subpixels SP, green subpixels SP, and blue subpixels SP. According to the example embodiment, at least some of the plurality of pixels may further include white subpixels SP. The plurality of subpixels SP may be variously modified in colors and configurations, as necessary or appropriate. However, the present disclosure is not limited thereto.

For example, the plurality of subpixels SP may include red, green, and blue subpixels, in which the red, green, and blue subpixels may be disposed in a repeated manner. Alternatively, the plurality of subpixels SP may include red, green, blue, and white subpixels, in which the red, green, blue, and white subpixels may be disposed in a repeated manner, or the red, green, blue, and white subpixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in the embodiment of the present disclosure, the color type, disposition type, and disposition order of the subpixels are not limiting, and may be configured in various forms according to light-emitting characteristics, device lifespans, and device specifications.

Meanwhile, the subpixels may have different light-emitting areas according to light-emitting characteristics. For example, a sub-pixel that emits light of a color different from that of a blue sub-pixel may have a different light-emitting area from that of the blue sub-pixel. For example, the red sub-pixel, the blue sub-pixel, and the green sub-pixel, or the red sub-pixel, the blue sub-pixel, the white sub-pixel, and the green sub-pixel may each has a different light-emitting area.

In detail, the display area DA can include a first area NTA in which a plurality of subpixels SP1, SP2, SP3 and SP4 are disposed, and a second area TA in which the plurality of subpixels SP1, SP2, SP3 and SP4 are not disposed. The first area NTA can be a non-transmissive area that does not transmit most of light incident from the outside. The second area TA can be a transmissive area through which most of light incident from the outside passes. For example, the transmissive area TA can be an area in which light transmittance is greater than x %, and the non-transmissive area NTA can be an area in which light transmittance is smaller than β%. In this case, a can be a value greater than β. A user can view an object or a background, which is positioned on a rear surface of the transparent display panel 110, due to the transmissive areas TA.

The non-transmissive area NTA can include a first non-transmissive area NTA1, a second non-transmissive area NTA2, and a pixel P.

The first non-transmissive area NTA1 can be extended in the first direction (e.g., Y-axis direction) in the display area DA, and can be disposed to at least partially overlap light emission areas EA1, EA2, EA3 and EA4. In the transparent display panel 110, a plurality of first non-transmissive areas NTA1 can be disposed to be spaced apart from each other, and the transmissive area TA can be disposed between two adjacent first non-transmissive areas NTA1. A plurality of first signal lines SL1 extended in the first direction (e.g., Y-axis direction) can be disposed to be spaced apart from each other in each of the first non-transmissive areas NTA1.

The first signal lines SL1 can include at least one of a first power line VDDL, a reference line REFL, data lines DL1, DL2, DL3 and DL4, or a second power line VSSL, as shown in FIG. 4.

The first power line VDDL can supply a first power source to a driving transistor of each of the subpixels SP1, SP2, SP3 and SP4 provided in the display area DA. The second power line VSSL can supply a second power source to a second electrode of the subpixels SP1, SP2, SP3 and SP4 provided in the display area DA. In this case, the second power source can be a common power source commonly supplied to the subpixels SP1, SP2, SP3 and SP4. The reference line REFL can supply an initialization voltage (or a reference voltage) to the driving transistor of each of the subpixels SP1, SP2, SP3 and SP4 provided in the display area DA. Each of the data lines DL1, DL2, DL3 and DL4 can supply a data voltage to the subpixels SP1, SP2, SP3 and SP4.

In the transparent display panel 110 according to an example embodiment of the present disclosure, a pixel P is provided between adjacent transmissive areas TA, and the pixel P can include light emission areas EA1, EA2, EA3 and EA4 in which a light emitting element is disposed to emit light. Since the transparent display panel 110 has a small size of the non-transmissive area NTA, the circuit element can be disposed to overlap the light emission areas EA1, EA2, EA3 and EA4. That is, at least a portion of the light emission areas EA1, EA2, EA3 and EA4 can overlap circuit areas CA1, CA2, CA3 and CA4 in which the circuit element is disposed.

For example, the circuit area can include a first circuit area CA1 in which the circuit element connected to the first subpixel SP1 is disposed, a second circuit area CA2 in which the circuit element connected to the second subpixel SP2 is disposed, a third circuit area CA3 in which the circuit element connected to the third subpixel SP3 is disposed, and a fourth circuit area CA4 in which the circuit element connected to the fourth subpixel SP4 is disposed.

The second non-transmissive area NTA2 can be extended in the second direction (e.g., X-axis direction) between two adjacent first non-transmissive areas NTA1. The second non-transmissive area NTA2 can be disposed between two adjacent transmissive areas TA. In the transparent display panel 110, a plurality of second non-transmissive areas NTA2 are disposed to be spaced apart from each other, and the transmissive area TA can be provided between two adjacent second non-transmissive areas NTA2. The second signal line SL2 can be disposed in the second non-transmissive area NTA2.

The second signal line SL2 can be extended in the second direction (e.g., X-axis direction), and can include, for example, a scan line SCANL. The scan line SCANL can supply a scan signal to the subpixels SP1, SP2, SP3 and SP4 of the pixel P.

Each of the pixels P is provided in the first non-transmissive area NTA1, and emits light to display an image. The light emission area EA can correspond to an area that emits light from the pixel P.

Each of the pixels P can include a first subpixel SP1, a second subpixel SP2, a third subpixel SP3, and a fourth subpixel SP4 as shown in FIGS. 2 and 4. The first subpixel SP1 can include a first light emission area EA1 that emits light of a first color, and the second subpixel SP2 can include a second light emission area EA2 that emits light of a second color. The third subpixel SP3 can include a third light emission area EA3 that emits light of a third color, and the fourth subpixel SP4 can include a fourth light emission area EA4 that emits light of a fourth color.

For example, the first to fourth light emission areas EA1, EA2, EA3 and EA4 can emit light of different colors. For example, the first light emission area EA1 can emit white light, and the second light emission area EA2 can emit green light. The third light emission area EA3 can emit red light, and the fourth light emission area EA4 can emit blue light. However, the present disclosure is not limited to the above example. Also, various modifications can be made in the arrangement order of the subpixels SP1, SP2, SP3 and SP4.

Meanwhile, the light emission areas EA1, EA2, EA3 and EA4 respectively provided in the plurality of subpixels SP1, SP3 and SP4 can include a plurality of light emission areas divided into a plural number. In detail, the first light emission area EA1 provided in the first subpixel SP1 can include a first sub-light emission area EA11 and a second sub-light emission area EA12, which are divided into two. The second light emission area EA2 provided in the second subpixel SP2 can include a first sub-light emission area EA21 and a second sub-light emission area EA22, which are divided into two. The third light emission area EA3 provided in the third subpixel SP3 can include a first sub-light emission area EA31 and a second sub-light emission area EA32, which are divided into two. The fourth light emission area EA4 provided in the fourth subpixel SP4 can include a first sub-light emission area EA41 and a second sub-light emission area EA42, which are divided into two. However, the present disclosure is not limited thereto, the light emission areas EA1, EA2, EA3 and EA4 respectively provided in the plurality of subpixels SP1, SP3 and SP4 can include a plurality of light emission areas divided into more than two, for example, the first light emission area EA1 provided in the first subpixel SP1 can include a first sub-light emission area, a second sub-light emission area and a third sub-light emission area, which are divided into three. The second light emission area EA2 provided in the second subpixel SP2 can include a first sub-light emission area, a second sub-light emission area and a third sub-light emission area, which are divided into three. The third light emission area EA3 provided in the third subpixel SP3 can include a first sub-light emission area, a second sub-light emission area and a third sub-light emission area, which are divided into three. The fourth light emission area EA4 provided in the fourth subpixel SP4 can include a first sub-light emission area, a second sub-light emission area and a third sub-light emission area, which are divided into three.

When each of the subpixels SP1, SP2, SP3 and SP4 is turned on by the scan signal of the scan line SCANL so that a data voltage of the data line DL is supplied to a gate electrode of the driving transistor, the light emitting element can emit light in accordance with a drain-source current of the driving transistor.

As shown in FIG. 3, each of the subpixels SP1, SP2, SP3, and S4 can have a 2T (transistor) 1C (capacitor) structure that includes two transistors DT and ST and one capacitor Cst, but is not limited thereto. Each of the subpixels SP1, SP2 and SP3 can further include a compensation circuit CC, and in this case, can have various structures such as 3T1C, 4T2C, 5T2C, 6T2C, 7T1C and 7T2C.

Each of the transistors DT and ST of each of the subpixels SP1, SP2, SP3 and SP4 includes a gate electrode, a source electrode, and a drain electrode. Since the source electrode and the drain electrode are not fixed and can be changed in accordance with a voltage and a current direction, which are applied to the gate electrode, one of the source electrode and the drain electrode can be expressed as a first electrode, and the other can be expressed as a second electrode. The transistors DT and ST of each of the subpixels SP1, SP2, SP3 and SP4 can use at least one of a polysilicon semiconductor, an amorphous silicon semiconductor, or an oxide semiconductor. The transistors DT and ST can be P-type or N-type transistors, or P-type and N-type transistors can be used interchangeably.

The transistors may be thin-film transistors TFTs. Active layers of thin-film transistors TFTs may be formed of a semiconductor material, such as an oxide semiconductor, amorphous semiconductor, or polycrystalline semiconductor, but is not limited thereto.

The oxide semiconductor material may have an excellent effect of preventing or reducing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polycrystalline silicon (poly-Si), but is not limited thereto.

The amorphous semiconductor material may be made of amorphous silicon (a-Si), but is not limited thereto.

The light emitting element ED can include an anode electrode connected to the driving transistor DT, a cathode electrode receiving a second power voltage EVSS from the second power line VSSL, and a light emitting layer between the anode electrode and the cathode electrode. The anode electrode is an independent electrode for each light emitting element, but the cathode electrode can be a common electrode shared by all of the light emitting elements. When a driving current is supplied from the driving transistor DT, electrons from the cathode electrode can be injected into the light emitting layer and holes from the anode electrode can be injected into the light emitting layer, so that the light emitting element ED can allow fluorescent or phosphorescent materials to emit light through recombination of the electrons and the holes in the light emitting layer, thereby generating light of brightness proportional to a current value of the driving current.

In each of the subpixels SP1, SP2, SP3 and SP4, the driving transistor DT is connected between the anode electrode of the light emitting element ED and the first power line VDDL for supplying a driving voltage EVDD. In this case, the driving voltage EVDD is applied to the first electrode of the driving transistor DT.

The driving transistor DT is a transistor for driving the light emitting element ED, and is controlled by a voltage applied to the gate electrode to supply a current to the light emitting element ED. Therefore, the light emitting element ED is driven.

In each of the subpixels SP1, SP2 and SP3, the switching transistor ST is connected between a first node N1 of the driving transistor DT and the data line DL. The switching transistor ST is controlled by a scan signal Scan supplied from the scan line SCANL to apply a data voltage Vdata supplied from the data line DL to the first node N1.

In each of the subpixels SP1, SP2, SP3 and SP4, the capacitor Cst is connected to the first node N1 to charge the voltage applied to the first node N1. The capacitor Cst can supply the charged driving voltage to the driving transistor DT. The capacitor Cst is a storage capacitor.

The compensation circuit CC can be provided to compensate for a threshold voltage of the driving transistor DT. The compensation circuit CC can be formed of one or more transistors. The compensation circuit CC can include one or more transistors and capacitors, and can be variously configured depending on a compensation method. A pixel that includes the compensation circuit CC can have various structures such as 3T1C, 4T2C, 5T2C, 6T1C, 7T1C and 7T2C.

Hereinafter, a circuit element, a light emitting element ED and an anode connection electrode ACE, which are provided in the transparent display panel 110 according to an example embodiment of the present disclosure, will be described in detail with reference to FIGS. 4 to 10.

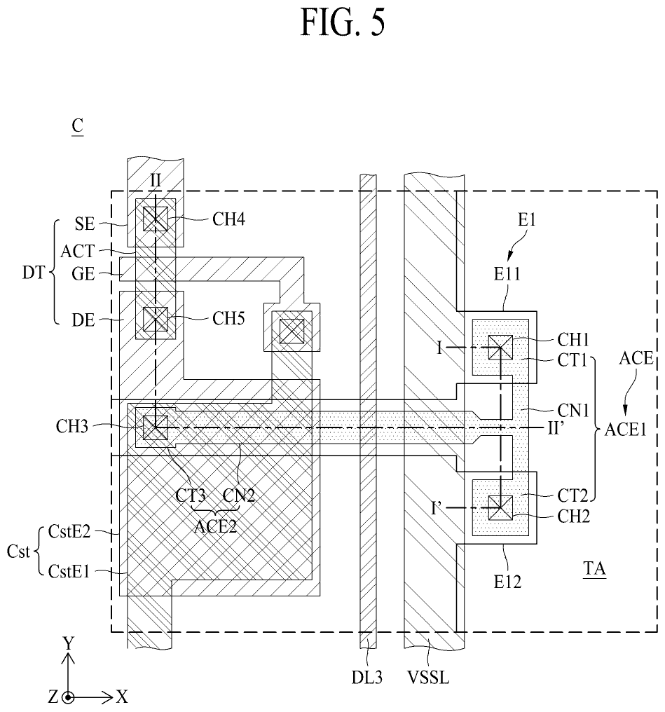

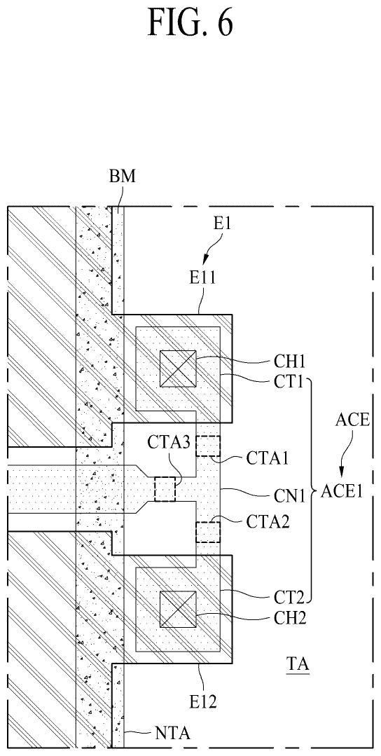

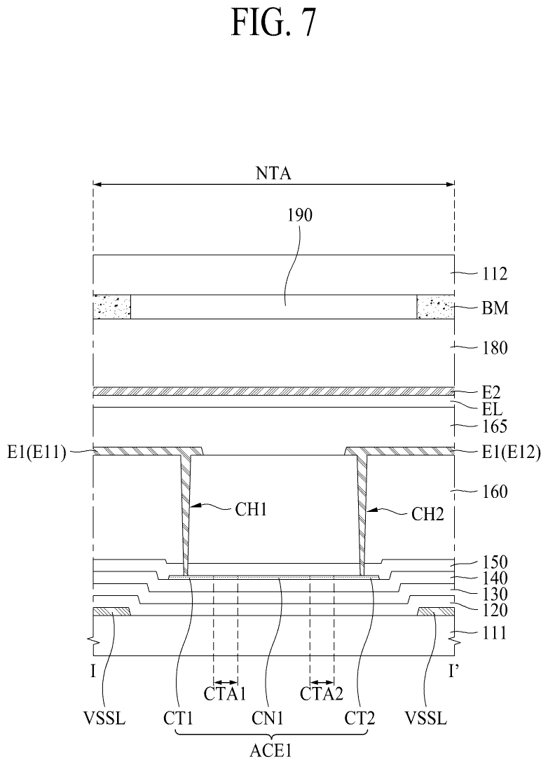

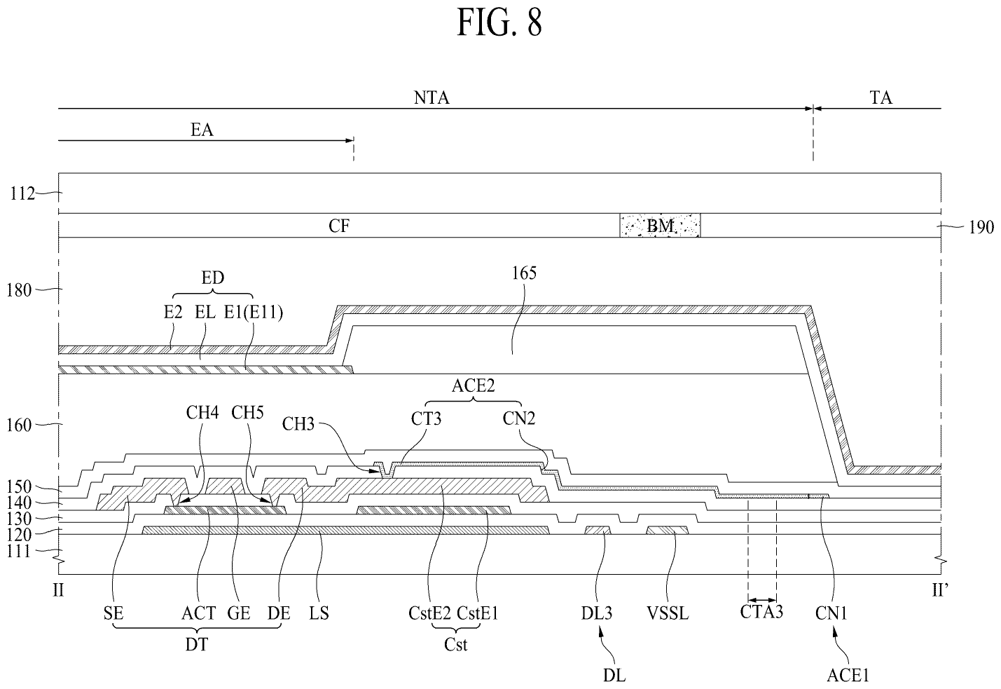

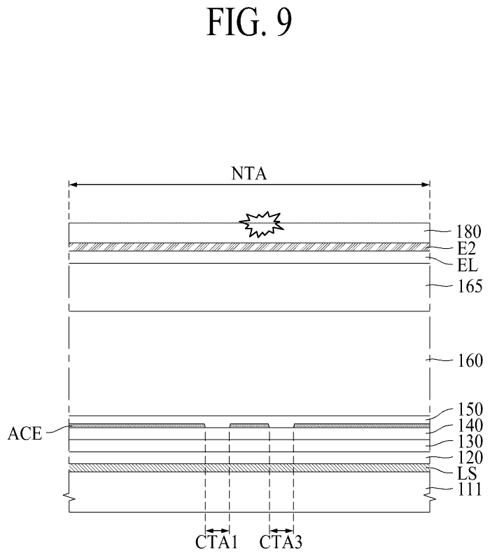

FIG. 5 is a plan view illustrating an example of an area C of FIG. 4, FIG. 6 is a plan view illustrating cutting areas of an anode connection electrode, FIG. 7 is a cross-sectional view illustrating an example of I-I′ of FIG. 5, FIG. 8 is a cross-sectional view illustrating an example of II-II′ of FIG. 5, and FIG. 9 is a view illustrating an example in which a cathode electrode and an encapsulation layer are damaged during laser cutting.

As shown in FIGS. 4 to 8, the transparent display panel 110 according to an example embodiment of the present disclosure includes a first substrate 111 and a second substrate 112, which face each other, and a circuit element, an anode connection electrode ACE, a light emitting element ED, an encapsulation layer 180, a color filter CF and a black matrix BM can be disposed between the first substrate 111 and the second substrate 112.

The circuit element is disposed for each of the subpixels SP1, SP2, SP3 and SP4 in the non-transmissive area NTA, and can include various signal lines, a thin film transistor, and a capacitor. The signal lines can include scan lines, data lines, power lines, and the like, and the thin film transistor can include a switching transistor and a driving transistor DT. The switching transistor can be switched in accordance with a scan signal supplied to a gate line to charge the capacitor Cst with a data voltage supplied from the data line.

The driving transistor DT and the capacitor Cst can be disposed in the non-transmissive area NTA and connected to the light emitting element ED of each of the plurality of subpixels SP1, SP2, SP3 and SP4.

The driving transistor DT includes an active layer ACT, a gate electrode GE, a source electrode SE, and a drain electrode DE. In addition, the capacitor Cst can include a first capacitor electrode CstE1 and a second capacitor electrode CstE2, but is not limited thereto. In another example embodiment, the capacitor Cst can further include a third capacitor electrode.

In detail, a light shielding layer LS can be provided on the first substrate 111. The light shielding layer LS may block external light and may prevent the characteristics of components disposed inside the display panel from changing due to external light. Additionally, the light shielding layer LS may include a metal material, and may transmit an electrical signal. The light shielding layer LS can be provided to overlap an area in which the driving transistor DT is formed, and can serve to block external light incident on the active layer ACT of the driving transistor DT. Also, the light shielding layer LS can be provided in an area in which an electrode made of the same material as that of the active layer ACT is formed on the same layer as the active layer ACT. For example, the first capacitor electrode CstE1 of the capacitor Cst can be formed of the same material on the same layer as the active layer ACT of the driving transistor DT as shown in FIG. 5. In this case, the light shielding layer LS can be provided to overlap the area in which the capacitor Cst is formed, and can shield external light incident on the first capacitor electrode CstE1 of the capacitor Cst.

The light shielding layer LS can be formed of a single layer or multi-layer made of any one of molybdenum (Mo), aluminum (Al), chromium (Cr), gold (Au), titanium (Ti), nickel (Ni), neodymium (Nd) and copper (Cu), or their alloy.

A buffer layer 120 can be provided on the light shielding layer LS. The buffer layer 120 is to protect the driving transistor DTR from impurities such as hydrogen and moisture, which are permeated through the first substrate 111 that is vulnerable to moisture permeation, and can be extended not only to the display area DA including the non-transmissive area NTA and the transmissive area TA but also to the non-display area NDA including the pad area PA. The buffer layer 120 can have a single layered structure or a multi-layered structure, which includes an inorganic insulating material such as silicon oxide (SiOx), silicon nitride (SiNx) and aluminum oxide (Al₂O₃). For example, the buffer layer 120 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto. However, the buffer layer 120 may be excluded in accordance with the structure or properties of the display device.

The active layer ACT of the driving transistor DT can be provided on the buffer layer 120. Also, the first capacitor electrode CstE1 of the capacitor Cst can be provided on the same layer as the active layer ACT of the driving transistor DT. In this case, the first capacitor electrode CstE1 of the capacitor Cst can be disposed to be spaced apart from the active layer ACT of the driving transistor DT. The first capacitor electrode CstE1 of the capacitor Cst and the active layer ACT of the driving transistor DT can be formed of a silicon-based semiconductor material or an oxide-based semiconductor material, but not limited thereto.

A gate insulating layer 130 can be provided on the first capacitor electrode CstE1 of the capacitor Cst and the active layer ACT of the driving transistor DT. The gate insulating layer 130 can be formed of an inorganic layer, for example, a silicon oxide layer (SiOx), a silicon nitride layer (SiNx), or a multi-layer thereof. For example, the gate insulating layer 130 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

The gate electrode GE, the source electrode SE and the drain electrode DE of the driving transistor DT can be disposed on the gate insulating layer 130. The gate electrode GE, the source electrode SE and the drain electrode DE of the driving transistor DT can be formed of the same material on the same layer as shown in FIG. 5, but are not limited thereto. In another example embodiment, the source electrode SE and the drain electrode DE of the driving transistor DT can be formed of a different material on a different layer from the gate electrode GE. The source electrode SE can be connected to the active layer ACT through a fourth contact hole CH4, and the drain electrode DE can be connected to the active layer ACT through a fifth contact hole CH5.

Also, the second capacitor electrode CstE2 of the capacitor Cst can be provided on the same layer as the gate electrode GE, the source electrode SE and the drain electrode DE of the driving transistor DT. The second capacitor electrode CstE2 of the capacitor Cst can be formed to be extended from the source electrode SE or the drain electrode DE of the driving transistor DT. Therefore, the second capacitor electrode CstE2 of the capacitor Cst can be electrically connected to the source electrode SE or the drain electrode DE of the driving transistor DT.

The second capacitor electrode CstE2 of the capacitor Cst, and the gate electrode GE, the source electrode SE and the drain electrode DE of the driving transistor DT can be formed of a single layer or multi-layer made of any one of molybdenum (Mo), aluminum (Al), chromium (Cr), gold (Au), titanium (Ti), nickel (Ni), neodymium (Nd) and copper (Cu), or their alloy.

A first insulating layer 140 can be provided on the second capacitor electrode CstE2 of the capacitor Cst and the gate electrode GE, the source electrode SE and the drain electrode DE of the driving transistor DT. The first insulating layer 140 can be formed of an inorganic layer, for example, a silicon oxide layer (SiOx), a silicon nitride layer (SiNx), or a multi-layer thereof. For example, the first insulating layer 140 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto. The first insulating layer 140 can be extended not only to the display area including the non-transmissive area NTA and the transmissive area TA but also to the non-display area NDA including the pad area PA.

An anode connection electrode ACE can be provided on the first insulating layer 140. The anode connection electrode ACE electrically connects the driving transistor DT to the first electrode E1 of the light emitting element ED. The detailed description of the anode connection electrode ACE will be described later.

A second insulating layer 150 for protecting the driving transistor DT, the capacitor Cst, and the anode connection electrode ACE can be provided on the anode connection electrode ACE. The second insulating layer 150 can be formed of an inorganic layer, for example, a silicon oxide layer (SiOx), a silicon nitride layer (SiNx), or a multi-layer thereof. For example, the second insulating layer 150 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto. The second insulating layer 150 can be extended not only to the display area DA but also to the non-display area NDA including the pad area PA.

A planarization layer 160 for planarizing a step difference due to the driving transistor DT, the capacitor Cst and the anode connection electrode ACE can be provided on the second insulation layer 150. The planarization layer 160 can be provided in the non-transmissive area NTA, and cannot be provided in at least a portion of the transmissive area TA. For example, the planarization layer 160 can include an opening area that overlaps at least a portion of the transmissive area TA. The planarization layer 160 can deteriorate transparency by causing refraction of light when the light is transmitted. Therefore, the transparent display panel 110 according to an example embodiment of the present disclosure can increase transparency by removing a portion of the planarization layer 160 from the transmissive area TA.

The planarization layer 160 can be formed of an organic layer such as an acrylic resin, an epoxy resin, a phenolic resin, a polyamide resin, or a polyimide resin.

Light emitting elements ED, which include a first electrode E1, a light emitting layer EL and a second electrode E2, and a bank 165 are provided on the planarization layer 160.

The first electrode E1 is disposed on the planarization layer 160, and can be electrically connected to the driving transistor DT. The first electrode E1 can be electrically connected to the source electrode SE or the drain electrode DE of the driving transistor DTR through the anode connection electrode ACE.

In detail, the first electrode E1 can be formed as a plurality of electrodes in each of a plurality of subpixels SP1, SP2, SP3 and SP4. For example, the first electrode E1 can include a first anode electrode E11 and a second anode electrode E12. The first anode electrode E11 can be disposed in the first sub-light emission areas EA11, EA21, EA31 and EA41, and the second anode electrode E12 can be disposed in the second sub-light emission areas EA12, EA22, EA32 and EA42. The first anode electrode E11 and the second anode electrode E12 can be disposed to be spaced apart from each other on the same layer.

The first anode electrode E11 and the second anode electrode E12 can be electrically connected to each other through the anode connection electrode ACE. The anode connection electrode ACE can include a first anode connection electrode ACE1 and a second anode connection electrode ACE2.

The first anode connection electrode ACE1 can have one end electrically connected to the first anode electrode E11 through a first contact hole CH1, and can have the other end electrically connected to the second anode electrode E12 through a second contact hole CH2. Therefore, the first anode connection electrode ACE1 can electrically connect the first anode electrode E11 with the second anode electrode E12.

The second anode connection electrode ACE2 can be protruded from one side of the first anode connection electrode ACE1 and extended to the area where the driving transistor DT is formed. The second anode connection electrode ACE2 can be electrically connected to the first anode connection electrode ACE1 at one end, and can be electrically connected to the source electrode SE or the drain electrode DE of the driving transistor DT at the other end through a third contact hole CH3. Therefore, the second anode connection electrode ACE2 can electrically connect the first anode electrode E11 and the second anode electrode E12 to the source electrode SE or the drain electrode DE of the driving transistor DTR.

For example, the first anode electrode E11 and the second anode electrode E12 can be electrically connected to each other through the first anode connection electrode ACE1, and can be electrically connected to the source electrode SE or the drain electrode DE of the driving transistor DTR through the second anode connection electrode ACE2.

The first electrode E1 that includes the first anode electrode E11 and the second anode electrode E12 can be provided for each of the subpixels SP1, SP2, SP3 and SP4, and cannot be provided in the transmissive area TA. The bank 165 is provided between the first electrodes E1 adjacent to each other, and thus the first electrodes E1 adjacent to each other can be electrically insulated from each other.

The first electrode E1 can be formed of a metal material having high reflectance, such as a stacked structure (Ti/Al/Ti) of aluminum and titanium, a stacked structure (ITO/AI/ITO) of aluminum and ITO, Ag alloy, a stacked structure (ITO/Ag alloy/ITO) of Ag alloy and ITO, MoTi alloy, and a stacked structure (ITO/MoTi alloy/ITO) of MoTi alloy and ITO. The Ag alloy can be an alloy of silver (Ag), palladium (Pd), copper (Cu) and the like. The MoTi alloy can be an alloy of molybdenum (Mo) and titanium (Ti). The first electrode E1 can be an anode electrode. Hereinafter, the first electrode E1 can be expressed as the anode electrode. The first electrode and the anode electrode can mean the same element.

The bank 165 can be disposed on the planarization layer 160. The bank 165 may be disposed at a boundary between the plurality of subpixels SP and suppress a color mixture of light beams from the plurality of subpixels SP. For example, the bank 165 can be provided between the first electrodes E1 respectively provided in the plurality of subpixels SP1, SP2, SP3 and SP4. For example, the bank 165 can be formed to cover an edge of each of the first electrodes E1 and expose a portion of each of the first electrodes E1. Therefore, the bank 165 can prevent or mitigate a problem in which the light emission efficiency is deteriorated due to the concentration of current at the ends of the first electrodes E1.

The bank 165 can define light emission areas EA1, EA2, EA3 and EA4 of the subpixels SP1, SP2, SP3 and SP4. The light emission areas EA1, EA2, EA3 and EA4 of the subpixels SP1, SP2, SP3 and SP4 represent areas where the first electrode E1, the light emitting layer EL and the second electrode E2 are sequentially stacked to emit light by combination of holes from the first electrode E1 and electrons from the second electrode E2 in the light emitting layer EL. In this case, the area where the bank 165 is not formed and the first electrode E1 is exposed can be the light emission areas EA1, EA2, EA3 and EA4.

The bank 165 can be formed of an organic film such as an acryl-based material, an epoxy-based material, a phenolic-based material, a polyamide-based material and a polyimide-based material. Meanwhile, the bank 165 may include an inorganic insulating material, such as silicon nitride (SiNx) or silicon oxide (SiOx), or the bank 165 may be formed of black resin. However, the present disclosure is not limited thereto.

The light emitting layer EL can be disposed on the first electrode E1. The light emitting layer EL can include an emission material layer EML that contains a light emitting material. The light emitting material can contain an organic material, an inorganic material, or a hybrid material. The light emitting layer EL can have a multi-layered structure. For example, the light emitting layer EL can further include at least one of a hole injection layer HIL, a hole transport layer HTL, an electron transport layer ETL or an electron injection layer EIL. In this case, when a voltage is applied to the first electrode E1 and the second electrode E2, holes and electrons move to the emission material layer through the hole transport layer and the electron transport layer, respectively, and are combined with each other in the emission material layer to emit light.

In an example embodiment, the light emitting layer EL can be a common layer commonly formed in the subpixels SP1, SP2, SP3 and SP4. In this case, the light emitting layer EL can be a white light emitting layer for emitting white light. The light emitting layer EL can be provided in the transmissive area TA as well as the non-transmissive area NTA that includes the light emission areas EA1, EA2, EA3 and EA4, but is not limited thereto. The light emitting layer EL can be patterned and formed only in the non-transmissive area NTA that includes the light emission areas EA1, EA2, EA3 and EA4. For example, the light emitting layer EL may be not disposed in the transmissive area TA.

In another example embodiment, the emission material layer of the light emitting layer EL can be formed for each of the subpixels SP1, SP2, SP3 and SP4. For example, a white light emitting layer for emitting white light can be formed in the first subpixel SP1, a green light emitting layer for emitting green light can be formed in the second subpixel SP2, a red light emitting layer for emitting red light can be formed in the third subpixel SP3, and a blue light emitting layer for emitting blue light can be formed in the fourth subpixel SP4. In this case, the emission material layer of the light emitting layer EL cannot be formed in the transmissive area TA. However, the hole injection layer HIL, the hole transport layer HTL, the electron transport layer ETL and the electron injection layer EIL except the emission material layer can be commonly formed in the subpixels SP1, SP2, SP3 and SP4, and can be also formed in the transmissive area TA.

The second electrode E2 can be disposed on the light emitting layer EL. The second electrode E2 can be a common layer commonly formed in the subpixels SP1, SP2, SP3 and SP4 to apply the same voltage.

The second electrode E2 can be formed of a transparent conductive material (TCO) such as ITO or IZO capable of transmitting light or a semi-transmissive conductive material such as magnesium (Mg), silver (Ag) or an alloy of magnesium (Mg) and silver (Ag). When the second electrode E2 is formed of a semi-transmissive metal material, light emission efficiency can be increased by a micro cavity. The second electrode E2 can be a cathode electrode of the light emitting element ED. Hereinafter, the second electrode E2 can be referred to as a cathode electrode. The second electrode and the cathode electrode can mean the same element.

As described above, each light emitting element ED may be composed of overlapping parts of the first electrode E1, the light emitting layer EL, and second electrode E2. A predetermined emission area may be formed by each light emitting element ED. For example, the emission area of each light emitting element ED may include an area where the first electrode E1, the light emitting layer EL, and second electrode E2 overlap.

The encapsulation layer 180 can be provided on the light emitting elements ED. The encapsulation layer 180 can be formed on the second electrode E2 to cover the second electrode E2. The encapsulation layer 180 serves to prevent oxygen or moisture from being permeated into the light emitting layer EL and the second electrode E2. To this end, the encapsulation layer 180 can include at least one inorganic layer and at least one organic layer. The encapsulation layer 180 can have a structure in which inorganic layers and organic layers are alternately stacked, but is not limited thereto.

For example, the encapsulation layer 180 has a structure in which inorganic encapsulation layers and organic encapsulation layers are alternately stacked, such that the encapsulation layer 180 may protect the light-emitting element while inhibiting moisture or oxygen from penetrating into the light-emitting element. For example, the encapsulation layer 180 may have a multi-insulating film structure in which organic films and inorganic films are stacked alternately. The inorganic film can block permeation of moisture or oxygen. The organic film may planarize a surface of the inorganic film. When the organic film and the inorganic film are stacked in multiple layers, a movement path of moisture or oxygen may be longer than that of a single layer, thereby effectively blocking the permeation of moisture and oxygen affecting the light emitting layer EL. For example, the encapsulation layer 180 includes a first inorganic encapsulation layer, a first organic encapsulation layer, and a second inorganic encapsulation layer stacked sequentially. For example, the encapsulation layer 180 includes a first inorganic encapsulation layer, a first organic encapsulation layer, a second inorganic encapsulation layer, a second organic encapsulation layer, and a third inorganic encapsulation layer stacked sequentially. However, the present disclosure is not limited thereto.

The first inorganic encapsulation layer, the second inorganic encapsulation layer, and the third inorganic encapsulation layer may serve to block the penetration of moisture or oxygen. The first inorganic encapsulation layer, the second inorganic encapsulation layer, and the third inorganic encapsulation layer may be made of an inorganic material, for example, an inorganic material such as silicon nitride (SiNx), silicon oxide (SiOx), or aluminum oxide (AlOx). However, the present disclosure is not limited thereto.

The first organic encapsulation layer is disposed between the first inorganic encapsulation layer and the second inorganic encapsulation layer, and the second organic encapsulation layer is disposed between the second inorganic encapsulation layer and the third inorganic encapsulation layer. The first organic encapsulation layer and the second organic encapsulation layer may each have a larger thickness than each of the first inorganic encapsulation layer, the second inorganic encapsulation layer, and the third inorganic encapsulation layer to adsorb or block particles that may be produced during a process of manufacturing the display device. The first organic encapsulation layer and the second organic encapsulation layer may fill cracks that may be formed in the first inorganic encapsulation layer and the second inorganic encapsulation layer. The first organic encapsulation layer and the second organic encapsulation layer may planarize an upper portion of the first inorganic encapsulation layer and an upper portion of the second inorganic encapsulation layer by covering particles on the first inorganic encapsulation layer and the second inorganic encapsulation layer respectively. For example, the first organic encapsulation layer may planarize an upper portion of the first inorganic encapsulation layer by covering particles on the first inorganic encapsulation layer. For example, the second organic encapsulation layer may planarize an upper portion of the second inorganic encapsulation layer by covering particles on the second inorganic encapsulation layer. The first organic encapsulation layer and the second organic encapsulation layer may be made of an organic material, and for example, epoxy polymer, acrylic polymer, or the like may be used. However, the present disclosure is not limited thereto.

Meanwhile, the encapsulation layer 180 is not limited to three or five layers, for example, n layers alternately stacked between inorganic encapsulation layer and organic encapsulation layer (where n is an integer greater than 3) may be included.

Meanwhile, although not shown in FIGS. 6 and 7, a capping layer can be additionally formed between the second electrode E2 and the encapsulation layer 180.

A color filter CF can be provided on the encapsulation layer 180. The color filter CF can be provided on one surface of the second substrate 112, which faces the first substrate 111. The color filter CF can be patterned for each of the subpixels SP1, SP2, and SP3.

In detail, the color filter CF can include a first color filter, a second color filter, a third color filter, and a fourth color filter. The first color filter can be disposed to correspond to the light emission area EA1 of the first subpixel SP1, and can be a white color filter for transmitting white light. The white color filter can be formed of a transparent organic material for transmitting white light. The second color filter can be disposed to correspond to the light emission area EA2 of the second subpixel SP2, and can be a green color filter for transmitting green light. The third color filter can be disposed to correspond to the light emission area EA3 of the third subpixel SP3, and can be a red color filter for transmitting red light. The fourth color filter can be disposed to correspond to the light emission area EA4 of the fourth subpixel SP4, and can be a blue color filter for transmitting blue light.

The black matrix BM can be provided between the color filters CF patterned for each of the subpixels SP1, SP2, SP3 and SP4. The black matrix BM can be provided between the subpixels SP1, SP2, SP3 and SP4, and can prevent color mixture between adjacent subpixels SP1, SP2, SP3 and SP4. Also, the black matrix BM can prevent light incident from the outside from being reflected on a plurality of signal lines provided between the subpixels SP1, SP2, SP3 and SP4.

In addition, the black matrix BM is provided between the transmissive area TA and the plurality of subpixels SP1, SP2, SP3 and SP4, so that light emitted from each of the plurality of subpixels SP1, SP2, SP3 and SP4 can be prevented from moving to the transmissive area TA. The black matrix BM can include a material that absorbs light, for example, a black dye that absorbs all light of a visible wavelength band.

The color filter CF and the black matrix BM described above are not provided in the transmissive area TA to maintain high light transmittance in the transmissive area TA.

The first substrate 111 provided with the light emitting elements ED and the second substrate 112 provided with the color filter CF and the black matrix BM can be bonded to each other by an adhesive layer 190. The adhesive layer can be an optically clear resin layer (OCR) or an optically clear adhesive film (OCA), but not limited thereto.

The transparent display panel 110 according to an example embodiment of the present disclosure can connect the anode electrode E1 to the driving transistor DT by using the anode connection electrode ACE. In detail, the anode connection electrode ACE can include a first anode connection electrode ACE1 and a second anode connection electrode ACE2. The first anode connection electrode ACE1 can be electrically connected to the first anode electrode E11 at one end through the first contact hole CH1, and can be electrically connected to the second anode electrode E12 at the other end through the second contact hole CH2.

The first anode connection electrode ACE1 can include a first contact portion CT1, a second contact portion CT2, and a first connection portion CN1. The first contact portion CT1 can be disposed on one side of the first anode electrode E11 to overlap at least a portion of the first anode electrode E11. The first anode electrode E11 can be provided with a protrusion protruded from one side toward the transmissive area TA to contact the first contact portion CT1. The first contact portion CT1 can overlap the protrusion of the first anode electrode E11. In this case, the first contact portion CT1 can be disposed between the black matrix BM and the transmissive area TA. The first contact portion CT1 can be connected to the first anode electrode E11 through the first contact hole CH1.

The second contact portion CT2 can be disposed on one side of the second anode electrode E12 to overlap at least a portion of the second anode electrode E12. The second anode electrode E12 can be provided with a protrusion protruded from one side toward the transmissive area TA to contact the second contact portion CT2. The second contact portion CT2 can overlap the protrusion of the second anode electrode E12. In this case, the second contact portion CT2 can be disposed between the black matrix BM and the transmissive area TA. The second contact portion CT2 can be connected to the second anode electrode E12 through the second contact hole CH2.

The first connection portion CN1 can connect the first contact portion CT1 with the second contact portion CT2. The first contact portion CT1 and the second contact portion CT2 can be disposed to be spaced apart from each other in a direction in which the first anode electrode E11 and the second anode electrode E12 are disposed. For example, the first anode electrode E11 and the second anode electrode E12 can be disposed to be spaced apart from each other in the first direction (e.g., Y-axis direction). In this case, the first contact portion CT1 and the second contact portion CT2 can be disposed to be spaced apart from each other in the first direction (e.g., Y-axis direction). The first connection portion CN1 can be extended in the first direction (e.g., Y-axis direction) to connect the first contact portion CT1 with the second contact portion CT2.

The first connection portion CN1 can have one end connected to the first contact portion CT1 and the other end connected to the second contact portion CT2. The first connection portion CN1 can have a straight line between the first contact portion CT1 and the second contact portion CT2.

Also, the first connection portion CN1 cannot be further protruded in the transmissive area TA than the first contact portion CT1 and the second contact portion CT2. One boundary between the first connection portion CN1 and the transmissive area TA cannot be further protruded in the transmissive area TA than one boundary between the first contact portion CT1 and the transmissive area TA and one boundary between the second contact portion CT2 and the transmissive area TA. For example, one boundary between the first connection portion CN1 and the transmissive area TA can constitute a straight line on a vertical line with one boundary between the first contact portion CT1 and the transmissive area TA and one boundary between the second contact portion CT2 and the transmissive area TA as shown in FIG. 5. For example, a width of the first connection portion CN1 in the second direction (e.g., X-axis direction) is less than a width of each of the first contact portion CT1 and the second contact portion CT2 in the second direction (e.g., X-axis direction) as shown in FIG. 5.

The first anode connection electrode ACE1 should be disposed in an area that does not overlap the black matrix BM, for a laser cutting process. The first anode connection electrode ACE1 can be disposed between the black matrix BM and the transmissive area TA. Therefore, the non-transmissive area NTA can have an area protruded from one side of the non-transmissive area NTA toward the transmissive area TA by the first anode connection electrode ACE1. As a result, a size of the transmissive area TA can be reduced, and further, light transmittance can be reduced.

In the transparent display panel 110 according to an example embodiment of the present disclosure, the first connection portion CN1 is formed not to be protruded in the transmissive area TA rather than the first contact portion CT1 and the second contact portion CT2, thereby minimizing the size of the area protruded from the non-transmissive area NTA toward the transmissive area TA. The transparent display panel 110 according to an example embodiment of the present disclosure can minimize a decrease in light transmittance due to the first anode connection electrode ACE1.

The second anode connection electrode ACE2 can include a third contact portion CT3 and a second connection portion CN2. The third contact portion CT3 can be disposed to overlap the driving transistor DT or the capacitor Cst. In detail, the third contact portion CT3 can overlap one of the source electrode SE and the drain electrode DE of the driving transistor DT or the first capacitor electrode CstE1 of the capacitor Cst.

For example, the third contact portion CT3 can be disposed to overlap the source electrode SE or the drain electrode DE of the driving transistor DT, and can be electrically connected to the source electrode SE or the drain electrode DE of the driving transistor DT through the third contact hole CH3.

As another example, the third contact portion CT3 can be disposed to overlap the first capacitor electrode CstE1 of the capacitor Cst, and can be electrically connected to the first capacitor electrode CstE1 of the capacitor Cst through the third contact hole CH3. Since the first capacitor electrode CstE1 of the capacitor Cst is extended from the source electrode SE or the drain electrode DE of the driving transistor DT, the third contact portion CT3 can be electrically connected to the source electrode SE or the drain electrode DE of the driving transistor DT through the first capacitor electrode CstE1 of the capacitor Cst.

The second connection portion CN2 can connect the third contact portion CT3 to the first anode connection electrode ACE1. The second connection portion CN2 can be connected to the third contact portion CT3 at one end. The second connection portion CN2 can be extended from one end toward the transmissive area TA, and can be connected to the first connection portion CN1 of the first anode connection electrode ACE1 at the other end. The second connection portion CN2 can be provided on the same layer as the first connection portion CN1. The second connection portion CN2 of the second anode connection electrode ACE2 can be protruded from one side of the first connection portion CN1 of the first anode connection electrode ACE1 and extended to the third contact portion CT3.

As described above, the first anode connection electrode ACE1 and the second anode connection electrode ACE2 can be in the non-transmissive areas NTA. The transmissive area TA can be provided between the first anode connection electrode ACE1 and the second anode connection electrode ACE2.

In the transparent display panel 110 according to an example embodiment of the present disclosure, when a defect occurs in at least one of the plurality of subpixels SP1, SP2, SP3 and SP4, at least a partial area of the anode connection electrode ACE can be cut to repair the defect. In detail, in the transparent display panel 110 according to an example embodiment of the present disclosure, particles or the like can be permeated into any one of the first anode electrode E11 and the second anode electrode E12 during the process, whereby a dark spot can occur. In this case, the transparent display panel 110 according to an example embodiment of the present disclosure can be repaired by cutting at least a partial area of the anode connection electrode ACE.

The anode connection electrode ACE can include a first cutting area CTA1, a second cutting area CTA2, and a third cutting area CTA3, as shown in FIG. 6.

In detail, the first anode connection electrode ACE1 can be provided with the first cutting area CTA1 and the second cutting area CTA2 in the first connection portion CN1. The first cutting area CTA1 can be provided between a point where the first anode connection electrode ACE1 and the second anode connection electrode ACE2 meet and the first contact portion CT1. The second cutting area CTA2 can be provided between the point where the first anode connection electrode ACE1 and the second anode connection electrode ACE2 meet and the second contact portion CT2.

In the transparent display panel 110 according to an example embodiment of the present disclosure, a defect can occur in an area of the first anode electrode E11 and the second anode electrode E12, in which the first anode electrode E11 is provided. Particles or the like can flow into the first anode electrode E11 during the process, whereby a short circuit can occur between the first anode electrode E11 and the second electrode E2. In this case, the first connection portion CN1 of the first anode connection electrode ACE1 can be cut using a laser by the first cutting area CTA1. As a result, the first anode electrode E11 can be electrically separated from the driving transistor DT and the second anode electrode E12. Even though the area in which the first anode electrode E11 is provided becomes a dark spot, the area in which the second anode electrode E12 is provided can normally operate to emit light.

On the contrary, in the transparent display panel 110 according to an example embodiment of the present disclosure, a defect can occur in an area of the first anode electrode E11 and the second anode electrode E12, in which the second anode electrode E12 is provided. Particles or the like can flow into the second anode electrode E12 during the process, whereby a short circuit can occur between the second anode electrode E12 and the second electrode E2. In this case, the first connection portion CN1 of the first anode connection electrode ACE1 can be cut using a laser by the second cutting area CTA2. As a result, the second anode electrode E12 can be electrically separated from the driving transistor DT and the first anode electrode E11. Even though the area in which the second anode electrode E12 is provided becomes a dark spot, the area in which the first anode electrode E11 is provided can normally operate to emit light.

The transparent display panel 110 according to an example embodiment of the present disclosure can reduce a light loss rate due to the occurrence of the defect by short-circuiting only the corresponding anode electrode of the plurality of divided anode electrodes E11 and E12 through laser cutting even though the defect occurs due to particles. When a defect can occur in an area, in which the first anode electrode E11 is provided, cutting the first connection portion CN1 of the first anode connection electrode ACE1 using a laser by the first cutting area CTA1, to electrically separate the first anode electrode E11 from the driving transistor DT and the second anode electrode E12. And when a defect occurs in an area in which the second anode electrode E12 is provided, cutting the first connection portion CN1 of the first anode connection electrode ACE1 using a laser by the second cutting area CTA2, to electrically separate the second anode electrode E12 from the driving transistor DT and the first anode electrode E11, thereby reducing a light loss rate due to the occurrence of the defect.

Also, in the transparent display panel 110 according to an example embodiment of the present disclosure, as shown in FIG. 6, the third cutting area CTA3 can be provided in the second anode connection electrode ACE2. The second anode connection electrode ACE2 can be provided with the third cutting area CTA3 in the second connection portion CN2. The second connection portion CN2 of the second anode connection electrode ACE2 can include a first area that overlaps the color filter CF and the black matrix BM, and a second area that does not overlap the color filter CF and the black matrix BM. The second connection portion CN2 of the second anode connection electrode ACE2 can be provided with the third cutting area CTA3 in the second area.

In the transparent display panel 110 according to an example embodiment of the present disclosure, a defect can occur in the circuit element, for example, the driving transistor DT. In this case, the second connection portion CN2 of the second anode connection electrode ACE2 can be cut using a laser by the third cutting area CTA3. As a result, the driving transistor DT can be electrically separated from the first anode electrode E11 and the second anode electrode E12.

In the transparent display panel 110 according to an example embodiment of the present disclosure, since the first anode electrode E11 and the second anode electrode E12 simultaneously become dark spots through a single laser cutting process, a repair process can be simplified. Furthermore, in the transparent display panel 110 according to an example embodiment of the present disclosure, since the number of times of irradiating the laser can be reduced, damage to elements provided in the area to which the laser is irradiated can be minimized.

Meanwhile, in the transparent display panel 110 according to an example embodiment of the present disclosure, the anode connection electrode ACE can be formed on a layer provided between the driving transistor DT and the anode electrode E1. The anode connection electrode ACE can be provided on a different layer from the gate electrode GE, the source electrode SE and the drain electrode DE of the driving transistor DT. The anode connection electrode ACE can be disposed on the gate electrode GE, the source electrode SE and the drain electrode DE of the driving transistor DT. Also, the anode connection electrode ACE can be provided on a different layer from the anode electrode E1. The anode connection electrode ACE can be disposed below the anode electrode E1, but not limited thereto.

The anode connection electrode ACE can be provided between a plurality of insulating layers provided between the driving transistor DT and the anode electrode E1. For example, the anode connection electrode ACE can be disposed between the first insulating layer 140 and the second insulating layer 150.

The anode connection electrode ACE can be formed of a material different from that of the gate electrode GE, the source electrode SE and the drain electrode DE of the driving transistor DT. Also, the anode connection electrode ACE can be formed of a material different from that of the anode electrode E1.

The anode connection electrode ACE can be made of a material having an oxidation degree lower than of each of the gate electrode GE, the source electrode SE and the drain electrode DE of the driving transistor DT. In other words, an oxidation degree of the material of the anode connection electrode ACE may be lower than an oxidation degree of a material of the gate electrode GE, lower than an oxidation degree of a material of the source electrode, and lower than an oxidation degree of a material of the drain electrode DE. For example, the anode connection electrode ACE can be formed of an alloy MoTi of molybdenum (Mo) and titanium (Ti) or can have a stacked structure of an alloy of molybdenum (Mo) and titanium (Ti) and ITO, but is not limited thereto.

The anode connection electrode ACE made of the above-described material can have a property of absorbing hydrogen particles. In the transparent display panel 110 according to an example embodiment of the present disclosure, the anode connection electrode ACE can absorb hydrogen generated therein, thereby preventing the light emitting element ED from being degraded by hydrogen, and furthermore, maintaining high emission efficiency even with low power, and reducing power consumption.

The anode connection electrode ACE can be formed to be thinner than the gate electrode GE, the source electrode SE and the drain electrode DE of the driving transistor DT. Each of the gate electrode GE, the source electrode SE and the drain electrode DE of the driving transistor DT should have a minimum thickness required or appropriate for operational reliability of the driving transistor DT. For example, each of the gate electrode GE, the source electrode SE and the drain electrode DE of the driving transistor DT can be formed to have a thickness of 6000 Å, but not limited thereto.

When the anode connection electrode ACE is formed of the same material on the same layer as the gate electrode GE, the source electrode SE or the drain electrode DE of the driving transistor DT, the anode connection electrode ACE can be formed to have the same thickness as that of the gate electrode GE, the source electrode SE or the drain electrode DE of the driving transistor DT. For example, the anode connection electrode ACE can be also formed to have a thickness of 6000 Å, but not limited thereto. Alternatively, the anode connection electrode ACE can be formed to have a different thickness from that of the gate electrode GE, the source electrode SE or the drain electrode DE of the driving transistor DT.

In this case, since the anode connection electrode ACE has a thick thickness, it is highly likely that one of the first cutting area CTA1, the second cutting area CTA2 and the third cutting area CTA3 is not completely cut in a cutting process using a laser. That is, the anode connection electrode ACE provided on the same layer as the gate electrode GE, the source electrode SE or the drain electrode DE of the driving transistor DT has a low cutting success rate in the laser cutting process, and thus a product defect rate can be increased.

In addition, to increase a cutting success rate for the anode connection electrode ACE, energy of a high level should be used during laser irradiation. For this reason, the possibility of damage to elements near the cutting area is increased. Moreover, since the anode connection electrode ACE is disposed to be adjacent to the anode electrode E1, the anode electrode E1 can be damaged.

In addition, the anode connection electrode ACE can include a plurality of cutting areas CTA1, CTA2 and CTA3. When a defect occurs in a specific subpixel, at least one of the plurality of cutting areas CTA1, CTA2 and CTA3 of the anode connection electrode ACE can be irradiated with a laser beam and cut. In some cases, two or more of the plurality of cutting areas CTA1, CTA2 and CTA3 of the anode connection electrode ACE can be irradiated with a laser beam and cut. For example, when a defect occurs in an area in which the first subpixel SP1 is provided, the first cutting area CTA1 of the anode connection electrode ACE can be irradiated with a laser beam and cut. However, since the anode connection electrode ACE provided on the same layer as the gate electrode GE, the source electrode SE or the drain electrode DE of the driving transistor DT is thick, the cutting can fail. In this case, it may be necessary or desirable to try a dark spot for all of the corresponding subpixels by irradiating a laser to the third cutting area CTA3.

At this time, when a gap distance between the first cutting area CTA1 and the third cutting area CTA3 is small and an energy level of the laser is high, as shown in FIG. 9, the cathode electrode E2 and the encapsulation layer 180, which are provided in the first cutting area CTA1 and the third cutting area CTA3, can be damaged by laser irradiation of twice, and degradation can occur in the light emitting element ED.

To prevent the anode electrode E1 from being damaged, the anode connection electrode ACE can be provided such that a gap distance between the cutting area and the anode electrode E1 is greater than or equal to a predetermined distance. Also, to prevent the cathode electrode E2 and the encapsulation layer 180 from being damaged, it may be necessary or desirable to make sure of a sufficient gap distance between the plurality of cutting areas CTA1, CTA2 and CTA3. For this reason, an area in which the anode connection electrode ACE is protruded in the transmissive area TA can be increased, an area of the transmissive area TA can be reduced, and light transmittance can be reduced.

In the transparent display panel 110 according to an example embodiment of the present disclosure, the anode connection electrode ACE can be provided on a different layer from the gate electrode GE, the source electrode SE or the drain electrode DE of the driving transistor DT. In this case, in the transparent display panel 110 according to an example embodiment of the present disclosure, the anode connection electrode ACE is formed to be thinner than the gate electrode GE, the source electrode SE or the drain electrode DE of the driving transistor DT, so that a cutting success rate in a laser cutting process can be increased. For example, the anode connection electrode ACE can be formed to have a thickness of 300 Å, but not limited thereto.

Since the anode connection electrode ACE has a thin thickness, it can be ensured that one of the first cutting area CTA1, the second cutting area CTA2 and the third cutting area CTA3 is completely cut in a cutting process using a laser. That is, the anode connection electrode ACE has a high cutting success rate, and thus, a product defect rate can be reduced. The transparent display panel 110 according to an example embodiment of the present disclosure can reduce manufacturing process costs, shorten the manufacturing process time, and further can reduce production energy. Furthermore, the transparent display panel 110 according to an example embodiment of the present disclosure can reduce occurrence of greenhouse gases that can occur due to a manufacturing process, thereby implementing environment/social/governance (ESG).

In addition, the anode connection electrode ACE can be well cut even when energy of low level is used during laser irradiation. The elements near the cutting area cannot be damaged in the laser cutting process.

Since the anode connection electrode ACE is well cut even with energy of a low level, the gap distance between the cutting area and the anode electrode E1 can be provided to be a minimum distance. In detail, each of the cutting areas CTA1 and CTA2 provided in the first connection portion CN1 of the first anode connection electrode ACE1 can be spaced apart from the black matrix BM by a minimum distance for laser irradiation. Also, even though the gap distance between the plurality of cutting areas CTA1, CTA2, and CTA3 of the anode connection electrode ACE is small, the cathode electrode E2 and the encapsulation layer 180 cannot be damaged. Therefore, the anode connection electrode ACE can be protruded to the minimum in the transmissive area TA, and the size of the transmissive area TA reduced due to the first anode connection electrode ACE1 can be minimized. Furthermore, the decrease in light transmittance due to the first anode connection electrode ACE1 can be minimized.

In the anode connection electrode ACE, the first connection portion CN1 in which the first cutting area CTA1 and the second cutting area CTA2 are formed can be less protruded in the transmissive area TA than the first contact portion CT1 and the second contact portion CT2. For example, the boundary between the first connection portion CN1 and the transmissive area TA can constitute a straight line on a vertical line with the boundary between the first contact portion CT1 and the transmissive area TA and the boundary between the second contact portion CT2 and the transmissive area TA. As a result, in the transparent display panel 110 according to an example embodiment of the present disclosure, since the boundary between the non-transmissive area NTA and the transmissive area TA is close to a straight line, haze can be reduced and image readability can be improved.

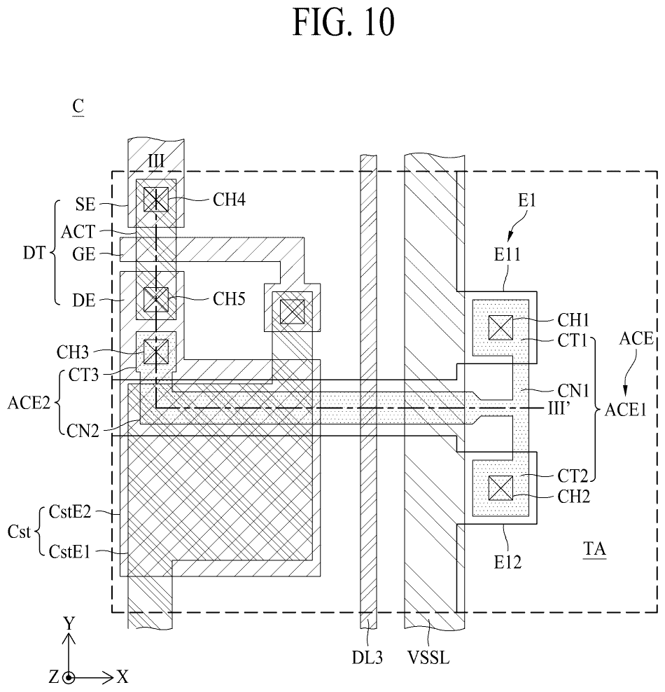

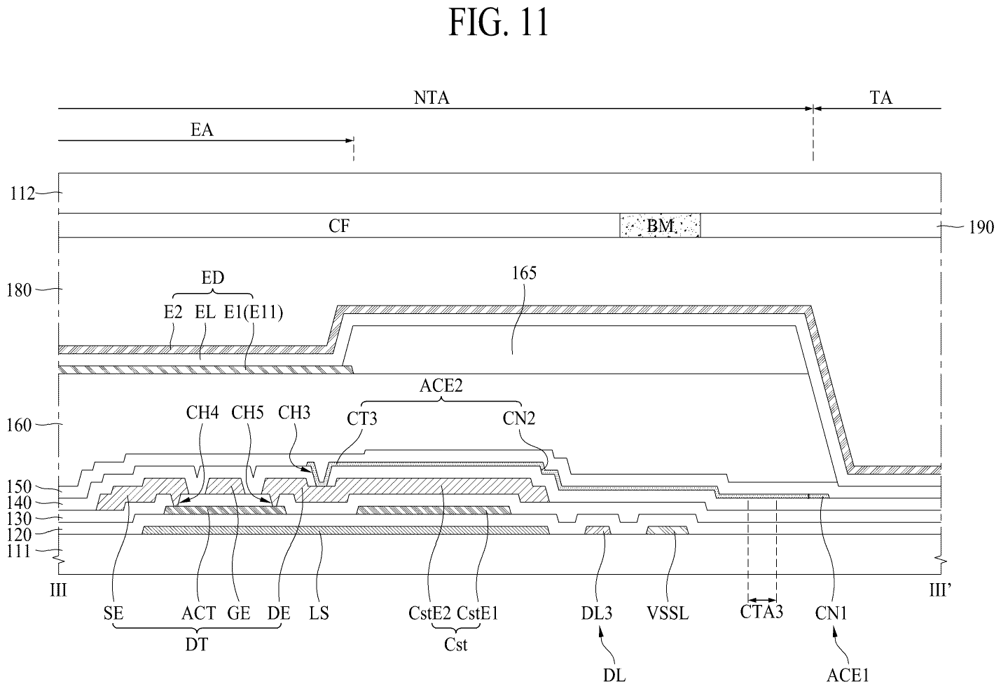

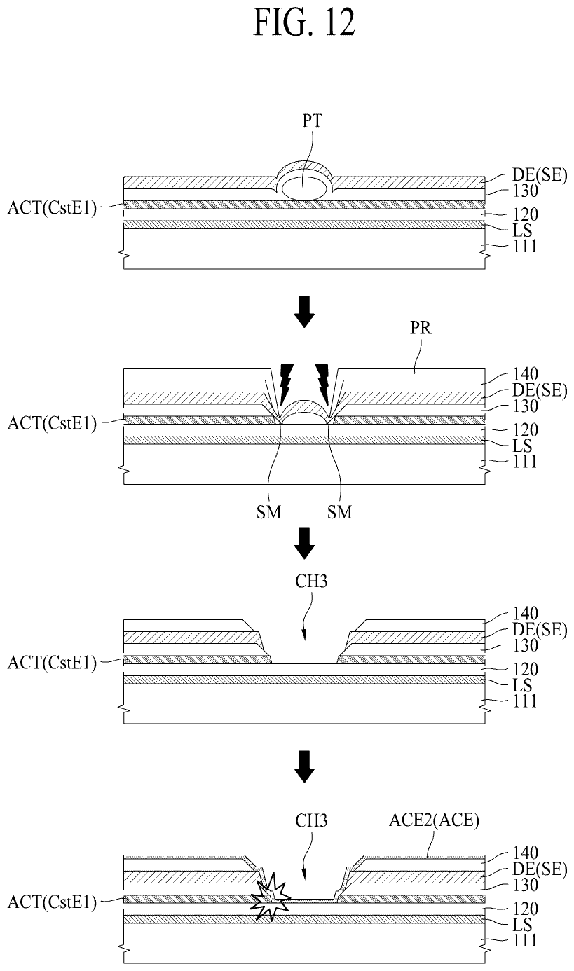

FIG. 10 is a plan view illustrating another example of an area C of FIG. 4, FIG. 11 is a cross-sectional view illustrating an example of III-III′ of FIG. 10, and FIG. 12 is a view illustrating an example in which a contact hole is formed in an area that overlaps an active layer.

The transparent display panel 110 shown in FIGS. 10 and 11 is different from the transparent display panel 110 shown in FIGS. 5 to 9 in only the anode connection electrode ACE, and the remaining elements are substantially the same as those shown in FIGS. 5 to 9. Hereinafter, a difference in relation to the anode connection electrode ACE will be mainly described, and a description of substantially the same elements will be omitted.

In the transparent display panel 110 according to an example embodiment of the present disclosure, the anode electrode E1 can be connected to the driving transistor DT by using the anode connection electrode ACE. In detail, the anode connection electrode ACE can include a first anode connection electrode ACE1 and a second anode connection electrode ACE2.

The first anode connection electrode ACE1 can be electrically connected to the first anode electrode E11 at one end through the first contact hole CH1, and can be electrically connected to the second anode electrode E12 at the other end through the second contact hole CH2. The first anode connection electrode ACE1 can include a first contact portion CT1, a second contact portion CT2 and a first connection portion CN1. The first contact portion CT1 can be connected to the first anode electrode E11 through the first contact hole CH1. The second contact portion CT2 can be connected to the second anode electrode E12 through the second contact hole CH2. The first connection portion CN1 can connect the first contact portion CT1 with the second contact portion CT2. The first connection portion CN1 can have one end connected to the first contact portion CT1 and the other end connected to the second contact portion CT2. The first connection portion CN1 can have a straight line between the first contact portion CT1 and the second contact portion CT2.

For the laser cutting process, the first anode connection electrode ACE1 can be disposed to be spaced apart from the black matrix BM without overlapping the same. That is, the first anode connection electrode ACE1 can be disposed between the black matrix BM and the transmissive area TA.

The second anode connection electrode ACE2 can include a third contact portion CT3 and a second connection portion CN2. The third contact portion CT3 can be disposed to overlap the driving transistor DT or the capacitor Cst. In detail, the third contact portion CT3 can overlap one of the source electrode SE and the drain electrode DE of the driving transistor DT or the first capacitor electrode CstE1 of the capacitor Cst.

For example, the third contact portion CT3 can be disposed to overlap the source electrode SE or the drain electrode DE of the driving transistor DT, and can be electrically connected to the source electrode SE or the drain electrode DE of the driving transistor DT through the third contact hole CH3.

As another example, the third contact portion CT3 can be disposed to overlap the first capacitor electrode CstE1 of the capacitor Cst, and can be electrically connected to the first capacitor electrode CstE1 of the capacitor Cst through the third contact hole CH3. Since the first capacitor electrode CstE1 of the capacitor Cst is extended from the source electrode SE or the drain electrode DE of the driving transistor DT, the third contact portion CT3 can be electrically connected to the source electrode SE or the drain electrode DE of the driving transistor DT through the first capacitor electrode CstE1 of the capacitor Cst. However, the present disclosure is not limited thereto.

The third contact portion CT3 of the second anode connection electrode ACE2 can be disposed between the active layer ACT of the driving transistor DT and the first capacitor electrode CstE1 of the capacitor Cst. That is, the third contact portion CT3 cannot overlap the active layer ACT of the driving transistor DT and the first capacitor electrode CstE1 of the capacitor Cst. Also, the third contact hole CH3 passing through the first insulating layer 140 cannot overlap the active layer ACT of the driving transistor DT and the first capacitor electrode CstE1 of the capacitor Cst.

When the third contact hole CH3 passing through the first insulating layer 140 overlaps the active layer ACT of the driving transistor DT or the first capacitor electrode CstE1 of the capacitor Cst, the active layer ACT of the driving transistor DT or the first capacitor electrode CstE1 of the capacitor Cst can be exposed by the third contact hole CH3. For this reason, the active layer ACT of the driving transistor DT or the first capacitor electrode CstE1 of the capacitor Cst can be in contact with the third contact portion CT3 of the second anode electrode ACE2 through the third contact hole CH3.

In more detail, the third contact portion CT3 of the second anode electrode ACE2 can overlap the first capacitor electrode CstE1 of the capacitor Cst provided on the same layer as the active layer ACT of the driving transistor DT.

The gate insulating layer 130 and the drain electrode DE (or the source electrode SE) can be sequentially stacked on the first capacitor electrode CstE1 of the capacitor Cst, as shown in FIG. 12. In some cases, particles PT generated in the manufacturing process can flow into the first capacitor electrode CstE1 of the capacitor Cst before the gate insulating layer 130 is deposited. Afterwards, the gate insulating layer 130 and the drain electrode DE (or the source electrode SE) can be sequentially stacked on the particles PT on the first capacitor electrode CstE1 of the capacitor Cst. In this case, a seam SM can be generated in the gate insulating layer 130 and the drain electrode DE (or the source electrode SE) due to the particles PT.

Then, the first insulating layer 140 can be formed on the drain electrode DE (or the source electrode SE). Then, a photoresist pattern PR for exposing an area in which the third contact hole CH3 is to be formed can be formed on the first insulating layer 140, and the first insulating layer 140 in an area that is not covered by the photoresist pattern PR can be removed using an etchant. In this case, the etchant can be permeated into the area of the seam SM generated by the particles PT. For this reason, the gate insulating layer 130 provided below the drain electrode DE (or the source electrode SE) and the first capacitor electrode CstE1 of the capacitor Cst can be also etched by the etchant. While the drain electrode DE (or the source electrode SE) is also torn off, a portion of the first capacitor electrode CstE1 of the capacitor Cst can be exposed through the third contact hole CH3.

Then, the anode connection electrode ACE can be formed between the first insulating layers 140. In this case, the anode connection electrode ACE can be electrically connected to the drain electrode DE (or the source electrode SE) of the driving transistor DT through the third contact hole CH3. In addition, the anode connection electrode ACE can be also in contact with a portion of the first capacitor electrode CstE1 of the capacitor Cst exposed from the third contact hole CH3, and thus can be electrically connected to the first capacitor electrode CstE1 of the capacitor Cst. The anode connection electrode ACE can be simultaneously connected to the drain electrode DE (or the source electrode SE) of the driving transistor DT and the first capacitor electrode CstE1 of the capacitor Cst, whereby a defect such as a bright spot can occur.

In the transparent display panel 110 according to another example embodiment of the present disclosure, the third contact hole CH3 can be disposed so as not to overlap the active layer ACT of the driving transistor DT and the first capacitor electrode CstE1 of the capacitor Cst, so that other electrodes except the drain electrode DE (or the source electrode SE) of the driving transistor DT can be prevented from being exposed from the third contact hole CH3.

In the transparent display panel 110 according to another example embodiment of the present disclosure, the position of the third contact hole CH3 can move between the active layer ACT of the driving transistor DT and the first capacitor electrode CstE1 of the capacitor Cst without a decrease in the size of the active layer ACT of the driving transistor DT and the first capacitor electrode CstE1 of the capacitor Cst. As a result, the transparent display panel 110 according to another example embodiment of the present disclosure can prevent a short circuit failure from occurring between the anode connection electrode ACE and the active layer ACT of the driving transistor DT or the first capacitor electrode CstE1 of the capacitor Cst while maintaining the size of the capacitor Cst.

The second connection portion CN2 can connect the third contact portion CT3 to the first anode connection electrode ACE1. The second connection portion CN2 can be connected to the third contact portion CT3 at one end, and can be extended in the direction of the transmissive area TA and then connected to the first connection portion CN1 of the first anode connection electrode ACE1 at the other end.

Example embodiments of the present disclosure described above are briefly described as follows.

According to example embodiments of the present disclosure, a transparent display device comprises: a first substrate including a transmissive area for transmitting external light and a non-transmissive area for not transmitting external light; a driving transistor provided in the non-transmissive area on the first substrate; an anode connection electrode provided on the driving transistor; and a light emitting element provided on the anode connection electrode, the light emitting element including an anode electrode, a light emitting layer, and a cathode electrode, wherein the anode electrode includes a first anode electrode and a second anode electrode, and wherein the anode connection electrode is electrically connected to the driving transistor at one side, and is extended toward the transmissive area from the non-transmissive area and electrically connected to each of the first anode electrode and the second anode electrode at the other side.

According to example embodiments of the present disclosure, the anode connection electrode is made of a material having an oxidation degree lower than of each of a gate electrode, a source electrode and a drain electrode of the driving transistor.

According to example embodiments of the present disclosure, the anode connection electrode includes: a first anode connection electrode electrically connected to the first anode electrode at one end through a first contact hole and electrically connected to the second anode electrode at the other end through a second contact hole; and a second anode connection electrode protruded from one side of the first anode connection electrode, extended to an area where the driving transistor is provided and electrically connected to the driving transistor through a third contact hole.

According to example embodiments of the present disclosure, a portion of the transmissive area is provided between the first anode connection electrode and the second anode connection electrode.

According to example embodiments of the present disclosure, the first anode connection electrode includes a first contact portion that overlaps the first contact hole and is connected to the first anode electrode through the first contact hole, a second contact portion that overlaps the second contact hole and is connected to the second anode electrode through the second contact hole, and a first connection portion connecting the first contact portion with the second contact portion in a straight line.

According to example embodiments of the present disclosure, a width of the first connection portion in a one direction is smaller than a width of each of the first contact portion and the second contact portion in the one direction.

According to example embodiments of the present disclosure, the first connection portion is less protruded in the transmissive area than the first contact portion and the second contact portion.

According to example embodiments of the present disclosure, one boundary between the first connection portion and the transmissive area constitutes a straight line on a vertical line with one boundary between the first contact portion and the transmissive area and one boundary between the second contact portion and the transmissive area.

According to example embodiments of the present disclosure, the first connection portion includes a first cutting area between a point where the first anode connection electrode and the second anode connection electrode meet and the first contact portion, and a second cutting area between a point where the first anode connection electrode and the second anode connection electrode meet and the second contact portion, and wherein the first cutting area is configured to be cut using a laser when a defect occurs in the first anode electrode, and the second cutting area is configured to be cut using a laser when a defect occurs in the second anode electrode.

According to example embodiments of the present disclosure, the transparent display device further comprises: a color filter disposed on the light emitting element; and a black matrix provided between the color filter and the transmissive area, wherein the first connection portion of the first anode connection electrode is spaced apart from the black matrix.

According to example embodiments of the present disclosure, the second anode connection electrode includes a third contact portion that overlaps the third contact hole and is connected to the driving transistor through the third contact hole, and a second connection portion connecting the third contact portion with the first connection portion of the first anode connection electrode, and wherein the second connection portion includes a first area that overlaps the color filter and the black matrix, and a second area that does not overlap the color filter and the black matrix.

According to example embodiments of the present disclosure, the second connection portion of the second anode connection electrode includes a third cutting area provided in the second area, and wherein the third cutting area is configured to be cut using a laser when a defect occurs in the driving transistor.

According to example embodiments of the present disclosure, the driving transistor includes an active layer, a gate electrode, a source electrode, and a drain electrode, wherein the second anode connection electrode includes a third contact portion that overlaps the third contact hole and is connected to the driving transistor through the third contact hole, and wherein the third contact portion of the second anode connection electrode does not overlap the active layer of the driving transistor.

According to example embodiments of the present disclosure, the transparent display device further comprises a capacitor including a first capacitor electrode provided on the same layer as the active layer of the driving transistor and a second capacitor electrode provided on the same layer as the gate electrode of the driving transistor, wherein the third contact portion of the second anode connection electrode does not overlap the first capacitor electrode of the capacitor.

According to example embodiments of the present disclosure, the third contact portion of the second anode connection electrode is disposed between the active layer of the driving transistor and the first capacitor electrode of the capacitor.

According to example embodiments of the present disclosure, the driving transistor includes an active layer, a gate electrode, a source electrode, and a drain electrode, and wherein a thickness of the anode connection electrode is less than a thickness of each of the gate electrode, the source electrode and the drain electrode of the driving transistor.

According to example embodiments of the present disclosure, the gate electrode, the source electrode, and the drain electrode are provided on the same layer.

According to example embodiments of the present disclosure, the anode connection electrode is connected to one of the source electrode and the drain electrode of the driving transistor through a third contact hole.

According to example embodiments of the present disclosure, the anode connection electrode includes molybdenum and titanium.

According to example embodiments of the present disclosure, a transparent display device comprises: a transmissive areas transmitting external light; a non-transmissive area provided between adjacent transmissive areas; a driving transistor provided in the non-transmissive area, the driving transistor including an active layer, a gate electrode, a source electrode, and a drain electrode; an anode connection electrode provided on the driving transistor; and a light emitting element provided on the anode connection electrode, the light emitting element including an anode electrode, a light emitting layer, and a cathode electrode, wherein the anode electrode includes a first anode electrode and a second anode electrode, and wherein the anode connection electrode electrically connects the first anode electrode and the second anode electrode to one of the source electrode and the drain electrode of the driving transistor.

According to example embodiments of the present disclosure, wherein the anode connection electrode includes a first anode connection electrode and a second anode connection electrode, and wherein a portion of the transmissive area is provided between the first anode connection electrode and the second anode connection electrode.

According to example embodiments of the present disclosure, the anode connection electrode is made of a material having an oxidation degree lower than of each of the gate electrode, the source electrode and the drain electrode of the driving transistor.

According to example embodiments of the present disclosure, a thickness of the anode connection electrode is less than a thickness of each of the gate electrode, the source electrode, and the drain electrode of the driving transistor.

According to example embodiments of the present disclosure, the anode connection electrode includes molybdenum and titanium.

According to example embodiments of the present disclosure, the gate electrode, the source electrode, and the drain electrode of the driving transistor are provided on the same layer.

According to example embodiments of the present disclosure, the anode connection electrode includes a first contact portion connected to the first anode electrode through a first contact hole, a second contact portion connected to the second anode electrode through a second contact hole, and a connection portion connecting the first contact portion with the second contact portion in a straight line.

According to example embodiments of the present disclosure, a width of the connection portion in one direction is smaller than a width of each of the first contact portion and the second contact portion in the one direction.

According to example embodiments of the present disclosure, the anode connection electrode includes a third contact portion connected to one of the source electrode and the drain electrode of the driving transistor through a third contact hole.

According to example embodiments of the present disclosure, an area in which the third contact portion is disposed is spaced apart from an area in which the active layer of the driving transistor is disposed.

According to example embodiments of the present disclosure, the transparent display device further comprises a capacitor including a first capacitor electrode and a second capacitor electrode, wherein the first capacitor electrode is provided on the same layer as the active layer of the driving transistor, and an area in which the third contact portion is disposed is disposed between an area in which the active layer of the driving transistor is disposed and an area in which the first capacitor electrode is disposed.

According to the present disclosure, the following advantageous effects can be obtained.

In the present disclosure, the anode connection electrode can be provided on a layer different from that of the gate electrode, the source electrode and the drain electrode of the driving transistor, so that the thickness of the anode connection electrode can be formed to be thin. Therefore, the present disclosure can increase a cutting success rate for the anode connection electrode in the laser cutting process.

Also, in the present disclosure, even though energy of low level is used during laser irradiation, cutting can be performed well. Therefore, in the present disclosure, the gap distance between the cutting area provided in the first anode connection electrode and the light emitting element can be reduced, and the gap distance between the plurality of cutting areas can be also reduced. Also, even though the gap distance between the cutting area provided in the first anode connection electrode and the light emitting element or the gap distance between the plurality of cutting areas is reduced, an influence on the elements disposed near the cutting area can be minimized.

Also, in the present disclosure, the product defect rate can be reduced, so that the manufacturing process cost can be reduced and the manufacturing process time can be shortened, and further production energy can be reduced. In addition, the present disclosure can reduce occurrence of greenhouse gases that can occur due to the manufacturing process, thereby implementing environment/social/governance (ESG).

Also, in the present disclosure, the size of the transmissive reduced due to the anode connection electrode can be minimized. Furthermore, the present disclosure can minimize the decrease in light transmittance due to the anode connection electrode.

Also, since the boundary between the non-transmissive area and the transmissive area is close to a straight line, haze can be reduced, and image readability can be improved.

Also, when a defect occurs only in one of the first and second anode electrodes, a partial area of the first anode connection electrode can be cut with a laser to short-circuit only the anode electrode where the defect occurs. In such a present disclosure, the size of the light emission area that becomes a dark spot can be reduced, whereby a light loss rate due to a defect can be minimized.

Also, in the present disclosure, the second anode connection electrode connected to the driving transistor can be cut with a laser so that the first and second anode electrodes can be simultaneously short circuited. In addition, the number of times of irradiation with the laser can be reduced so that the cathode electrode and the encapsulation layer can be prevented from being damaged due to a plurality of laser irradiation times. Furthermore, the light emitting element can be prevented from being degraded, whereby lifespan of the light emitting element can be increased.

Also, in the present disclosure, the contact hole through which the source electrode or the drain electrode of the driving transistor is in contact with the anode connection electrode can be disposed not to overlap the active layer, so that other electrodes except the source electrode or the drain electrode of the driving transistor can be prevented from being exposed from the contact hole. Further, the present disclosure can prevent a short circuit failure from occurring between the anode connection electrode and the active layer while maintaining the size of the capacitor.

It will be apparent to those skilled in the art that the present disclosure described above is not limited by the above-described example embodiments and the accompanying drawings and that various substitutions, modifications and variations can be made in the present disclosure without departing from the spirit or scope of the disclosures. Consequently, the protected scope of the present disclosure is defined by the accompanying claims and their equivalents, and it is intended that all variations or modifications derived from the meaning, scope, and equivalent concept of the claims fall within the scope of the present disclosure.

What is claimed is:

1. A transparent display device, comprising:
a first substrate including a transmissive area for transmitting external light and a non-transmissive area for not transmitting external light;
a driving transistor in the non-transmissive area on the first substrate;
an anode connection electrode on the driving transistor; and
a light emitting element on the anode connection electrode, the light emitting element including an anode electrode, a light emitting layer, and a cathode electrode,
wherein the anode electrode includes a first anode electrode and a second anode electrode, and
wherein the anode connection electrode is electrically connected to the driving transistor at one side, and is extended toward the transmissive area from the non-transmissive area and electrically connected to each of the first anode electrode and the second anode electrode at the other side.

2. The transparent display device of claim 1, wherein the anode connection electrode is made of a material having an oxidation degree lower than of each of a gate electrode, a source electrode, and a drain electrode of the driving transistor.

3. The transparent display device of claim 1, wherein the anode connection electrode includes:
a first anode connection electrode electrically connected to the first anode electrode at one end through a first contact hole and electrically connected to the second anode electrode at the other end through a second contact hole; and
a second anode connection electrode protruded from one side of the first anode connection electrode, extended to an area where the driving transistor is provided, and electrically connected to the driving transistor through a third contact hole.

4. The transparent display device of claim 3, wherein a portion of the transmissive area is provided between the first anode connection electrode and the second anode connection electrode.

5. The transparent display device of claim 3, wherein the first anode connection electrode includes a first contact portion that overlaps the first contact hole and is connected to the first anode electrode through the first contact hole, a second contact portion that overlaps the second contact hole and is connected to the second anode electrode through the second contact hole, and a first connection portion connecting the first contact portion with the second contact portion in a straight line.

6. The transparent display device of claim 5, wherein a width of the first connection portion in a one direction is smaller than a width of each of the first contact portion and the second contact portion in the one direction.

7. The transparent display device of claim 5, wherein the first connection portion is less protruded in the transmissive area than the first contact portion and the second contact portion.

8. The transparent display device of claim 5, wherein one boundary between the first connection portion and the transmissive area constitutes a straight line on a vertical line with one boundary between the first contact portion and the transmissive area and one boundary between the second contact portion and the transmissive area.

9. The transparent display device of claim 5, wherein:
the first connection portion includes a first cutting area between a point where the first anode connection electrode and the second anode connection electrode meet and the first contact portion, and a second cutting area between a point where the first anode connection electrode and the second anode connection electrode meet and the second contact portion; and
the first cutting area is configured to be cut using a laser when a defect occurs in the first anode electrode, and the second cutting area is configured to be cut using a laser when a defect occurs in the second anode electrode.

10. The transparent display device of claim 5, further comprising:
a color filter on the light emitting element; and
a black matrix between the color filter and the transmissive area,
wherein the first connection portion of the first anode connection electrode is spaced apart from the black matrix.

11. The transparent display device of claim 10, wherein:
the second anode connection electrode includes a third contact portion that overlaps the third contact hole and is connected to the driving transistor through the third contact hole, and a second connection portion connecting the third contact portion with the first connection portion of the first anode connection electrode; and
the second connection portion includes a first area that overlaps the color filter and the black matrix, and a second area that does not overlap the color filter and the black matrix.

12. The transparent display device of claim 11, wherein:
the second connection portion of the second anode connection electrode includes a third cutting area provided in the second area; and
the third cutting area is configured to be cut using a laser when a defect occurs in the driving transistor.

13. The transparent display device of claim 3, wherein:
the driving transistor includes an active layer, a gate electrode, a source electrode, and a drain electrode;
the second anode connection electrode includes a third contact portion that overlaps the third contact hole and is connected to the driving transistor through the third contact hole; and
the third contact portion of the second anode connection electrode does not overlap the active layer of the driving transistor.

14. The transparent display device of claim 13, further comprising a capacitor including a first capacitor electrode provided on the same layer as the active layer of the driving transistor and a second capacitor electrode provided on the same layer as the gate electrode of the driving transistor,
wherein the third contact portion of the second anode connection electrode does not overlap the first capacitor electrode of the capacitor.

15. The transparent display device of claim 14, wherein the third contact portion of the second anode connection electrode is disposed between the active layer of the driving transistor and the first capacitor electrode of the capacitor.

16. The transparent display device of claim 1, wherein:
the driving transistor includes an active layer, a gate electrode, a source electrode, and a drain electrode; and
a thickness of the anode connection electrode is less than a thickness of each of the gate electrode, the source electrode and the drain electrode of the driving transistor.

17. The transparent display device of claim 16, wherein the gate electrode, the source electrode, and the drain electrode are provided on the same layer.

18. The transparent display device of claim 16, wherein the anode connection electrode is connected to one of the source electrode and the drain electrode of the driving transistor through a third contact hole.

19. The transparent display device of claim 1, wherein the anode connection electrode includes molybdenum and titanium.

20. A transparent display device, comprising:
a plurality of transmissive areas transmitting external light;
a non-transmissive area between adjacent transmissive areas among the plurality of transmissive areas;
a driving transistor in the non-transmissive area, the driving transistor including an active layer, a gate electrode, a source electrode, and a drain electrode;
an anode connection electrode on the driving transistor; and
a light emitting element on the anode connection electrode, the light emitting element including an anode electrode, a light emitting layer, and a cathode electrode,
wherein the anode electrode includes a first anode electrode and a second anode electrode, and
wherein the anode connection electrode electrically connects the first anode electrode and the second anode electrode to one of the source electrode and the drain electrode of the driving transistor.

21. The transparent display device of claim 20, wherein:
the anode connection electrode includes a first anode connection electrode and a second anode connection electrode; and
a portion of a transmissive area of the plurality of transmissive areas is between the first anode connection electrode and the second anode connection electrode.

22. The transparent display device of claim 20, wherein the anode connection electrode is made of a material having an oxidation degree lower than that of each of the gate electrode, the source electrode, and the drain electrode of the driving transistor.

23. The transparent display device of claim 20, wherein a thickness of the anode connection electrode is less than a thickness of each of the gate electrode, the source electrode, and the drain electrode of the driving transistor.

24. The transparent display device of claim 20, wherein the anode connection electrode includes molybdenum and titanium.

25. The transparent display device of claim 20, wherein the gate electrode, the source electrode, and the drain electrode of the driving transistor are provided on the same layer.

26. The transparent display device of claim 20, wherein the anode connection electrode includes a first contact portion connected to the first anode electrode through a first contact hole, a second contact portion connected to the second anode electrode through a second contact hole, and a connection portion connecting the first contact portion with the second contact portion in a straight line.

27. The transparent display device of claim 26, wherein a width of the connection portion in one direction is smaller than a width of each of the first contact portion and the second contact portion in the one direction.

28. The transparent display device of claim 20, wherein the anode connection electrode includes a third contact portion connected to one of the source electrode and the drain electrode of the driving transistor through a third contact hole.

29. The transparent display device of claim 28, wherein an area in which the third contact portion is disposed is spaced apart from an area in which the active layer of the driving transistor is disposed.

30. The transparent display device of claim 28, further comprising a capacitor including a first capacitor electrode and a second capacitor electrode,
wherein the first capacitor electrode is provided on the same layer as the active layer of the driving transistor, and
wherein an area in which the third contact portion is disposed is disposed between an area in which the active layer of the driving transistor is disposed and an area in which the first capacitor electrode is disposed.
